(19) United States
(12) Patent Application Publication
(10) Pub. No.: US 2026/0020411 A1
(43) Pub. Date: Jan. 15, 2026

(54) LIGHT EMITTING ELEMENT, DISPLAY DEVICE AND ELECTRONIC DEVICE INCLUDING THE SAME, AND METHOD OF MANUFACTURING THE DISPLAY DEVICE

(71) Applicant: Samsung Display Co., LTD., Yongin-si (KR)

(72) Inventors: Hoo Keun PARK, Yongin-si (KR); Jong Moo HUH, Yongin-si (KR); Moon Jung AN, Yongin-si (KR)

(21) Appl. No.: 19/078,133

(22) Filed: Mar. 12, 2025

(30) Foreign Application Priority Data
Jul. 9, 2024 (KR) 10-2024-0090101

(51) Int. Cl. H10H 29/855; H01L 25/075; H10H 29/01

(52) U.S. Cl. CPC H10H 29/855; H01L 25/0753; H10H 29/012; H10H 29/0363

(57) ABSTRACT

A display device includes: a substrate; pixel electrodes on the substrate; and light emitting elements on the pixel electrodes, where each of the light emitting elements includes: a semiconductor stack including a first semiconductor layer, an active layer on the first semiconductor layer, and a second semiconductor layer on the active layer; light extraction patterns on a light output surface of the semiconductor stack and including groove portions that are spaced from an end of the light output surface and protrusion portions around the groove portions; and a protective layer covering side surfaces of the semiconductor stack, and where the light emitting elements include the light extraction patterns having a same shape.

### CROSS-REFERENCE TO RELATED APPLICATION

The present application claims priority to and the benefit of Korean Patent Application No. 10-2024-0090101, filed on Jul. 9, 2024, in the Korean Intellectual Property Office, the entire disclosure of which is incorporated by reference herein.

### BACKGROUND

### 1. Field

The present disclosure relates to a light emitting element, a display device and an electronic device including the same, and a method of manufacturing the display device.

### 2. Description of the Related Art

As the information society develops, demands for display devices for displaying images are increasing in various forms. Accordingly, various types of display devices including light emitting display devices are being developed.

A light emitting display device may include a light emitting element such as an organic light emitting element such as an organic light emitting diode (OLED) or an ultrasmall light emitting element such as a micro-light emitting diode (micro-LED) or a nano-light emitting diode (nano-LED). Because ultrasmall light emitting elements are made of inorganic materials, they have less deterioration issues and thus a longer life than organic light emitting elements.

### SUMMARY

Aspects and features of embodiments of the present disclosure provide a light emitting element with improved light output characteristics, a display device and an electronic device including the same, and a method of manufacturing the display device.

However, aspects and features of embodiments of the present disclosure are not restricted to the one set forth herein. The above and other aspects and features of the present disclosure will become more apparent to one of ordinary skill in the art to which the present disclosure pertains by referencing the detailed description of the present disclosure given below.

According to one or more embodiments of the present disclosure, a display device includes: a substrate; pixel electrodes on the substrate; and light emitting elements on the pixel electrodes, wherein each of the light emitting elements includes: a semiconductor stack including a first semiconductor layer, an active layer on the first semiconductor layer, and a second semiconductor layer on the active layer; light extraction patterns on a light output surface of the semiconductor stack and including groove portions that are spaced from an end of the light output surface and protrusion portions around the groove portions; and a protective layer covering side surfaces of the semiconductor stack, and wherein the light emitting elements include the light extraction patterns having a same shape.

In one or more embodiments, the light extraction patterns are arranged in a same structure on the light output surface of each of the light emitting elements.

In one or more embodiments, the light emitting elements include a same number of light extraction patterns.

In one or more embodiments, an outermost light extraction pattern on the light output surface of each of the light emitting elements is spaced from the end of the light output surface and located inside the light output surface.

In one or more embodiments, the light extraction patterns are arranged in a plurality of columns including a first column and a second column on the light output surface of each of the light emitting elements.

In one or more embodiments, a light extraction pattern closest to a first end of the light output surface from among light extraction patterns in the first column and a light extraction pattern closest to the first end of the light output surface from among light extraction patterns in the second column are spaced from the first end of the light output surface by a same distance.

In one or more embodiments, a light extraction pattern closest to a first end of the light output surface from among light extraction patterns in the first column and a light extraction pattern closest to the first end of the light output surface from among light extraction patterns in the second column are spaced from the first end of the light output surface by different distances.

In one or more embodiments, at least one light extraction pattern from among the light extraction patterns contacts the end of the light output surface.

In one or more embodiments, the at least one light extraction pattern contacts the end of the light output surface at the protrusion portion and is covered with the protective layer.

In one or more embodiments, the light extraction patterns are formed on an upper surface of the second semiconductor layer.

In one or more embodiments, a method of manufacturing a display device, the method including: forming light emitting elements, which include light extraction patterns; and placing the light emitting elements on a display substrate, wherein the light extraction patterns are on a light output surface of each of the light emitting elements and include groove portions that are spaced from an end of the light output surface and protrusion portions around the groove portions.

In one or more embodiments, the forming of the light emitting elements includes: preparing a semiconductor substrate, which includes light emitting element areas; forming uniform patterns inside the light emitting element areas to align with the light emitting element areas; forming a semiconductor material layer on a surface of the semiconductor substrate, which includes the patterns; and forming light emitting elements in the light emitting element areas by etching the semiconductor material layer.

In one or more embodiments, the forming of the light emitting elements includes: forming a semiconductor material layer on a semiconductor substrate, which includes light emitting element areas; forming light emitting elements in the light emitting element areas by etching the semiconductor material layer; transferring the light emitting elements to a transfer substrate such that the light output surfaces of the light emitting elements are exposed; placing a mask having a uniform pattern on the light output surfaces of the light emitting elements; and forming the light extraction patterns by etching the light output surfaces of the light emitting elements.

In one or more embodiments, the method further includes performing a subsequent pixel process, which includes forming a capping layer to cover the light emitting elements.

In one or more embodiments, a light emitting element includes: a semiconductor stack, which includes a first semiconductor layer, an active layer on the first semiconductor layer, and a second semiconductor layer on the active layer; a protective layer covering side surfaces of the semiconductor stack; and light extraction patterns on a light output surface of the semiconductor stack, the light extraction patterns including groove portions that are spaced from an end of the light output surface and protrusion portions around the groove portions.

In one or more embodiments, an outermost light extraction pattern from among the light extraction patterns is spaced from the end of the light output surface and located inside the light output surface.

In one or more embodiments, the light extraction patterns are arranged in a plurality of columns including a first column and a second column along a first direction.

In one or more embodiments, a light extraction pattern closest to a first end of the light output surface from among light extraction patterns in the first column and a light extraction pattern closest to the first end of the light output surface from among light extraction patterns in the second column are spaced from the first end of the light output surface by a same distance.

In one or more embodiments, a light extraction pattern closest to a first end of the light output surface from among light extraction patterns in the first column and a light extraction pattern closest to the first end of the light output surface from among light extraction patterns in the second column are spaced from the first end of the light output surface by different distances.

In one or more embodiments, wherein at least one of the light extraction patterns contacts the end of the light output surface.

In one or more embodiments, an electronic device for providing an image, includes a display device including: a substrate; pixel electrodes on the substrate; and light emitting elements on the pixel electrodes, wherein each of the light emitting elements includes: a semiconductor stack including a first semiconductor layer, an active layer on the first semiconductor layer, and a second semiconductor layer on the active layer; light extraction patterns on a light output surface of the semiconductor stack and including groove portions that are spaced from an end of the light output surface and protrusion portions around the groove portions; and a protective layer covering side surfaces of the semiconductor stack, and wherein the light emitting elements include light extraction patterns having a same shape.

In a light emitting element, a display device and an electronic device including the same, and a method of manufacturing the display device according to one or more embodiments, light extraction patterns can be uniformly disposed on a light output surface of the light emitting element, and side surfaces of a semiconductor stack can be stably covered with a protective layer. Accordingly, the light output characteristics of the light emitting element can be made uniform, and the light output rate of the light emitting element can be improved while the electrical stability of the light emitting element is secured.

However, effects according to the embodiments of the present disclosure are not limited to those exemplified above and various other effects are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to one or more embodiments;

FIG. 2 is a layout view of the display device according to one or more embodiments;

FIG. 3 is a block diagram of the display device according to one or more embodiments;

FIG. 4 is an equivalent circuit diagram of a subpixel according to one or more embodiments;

FIG. 5 is a layout view illustrating pixels of a display area according to one or more embodiments;

FIG. 6 is a layout view illustrating pixels of a display area according to one or more embodiments;

FIG. 7 is a cross-sectional view illustrating an example of a cross section of a display panel corresponding to the line 11-11′ of FIG. 6;

FIG. 8 is a detailed cross-sectional view of an embodiment of an area A1 of FIG. 7;

FIG. 9 is a detailed cross-sectional view of an embodiment of the area A1 of FIG. 7;

FIG. 10 is a detailed cross-sectional view of an embodiment of the area A1 of FIG. 7;

FIG. 11 is a detailed cross-sectional view of an embodiment of the area A1 of FIG. 7;

FIG. 12 is a detailed cross-sectional view of an embodiment of the area A1 of FIG. 7;

FIG. 13 is a detailed cross-sectional view of an embodiment of the area A1 of FIG. 7;

FIG. 14 is a cross-sectional view illustrating an example of a cross section of a display panel corresponding to the line 11-11′ of FIG. 6;

FIG. 15 is a detailed cross-sectional view of an embodiment of an area A2 of FIG. 14;

FIG. 16 is a layout view illustrating pixels of a display area according to one or more embodiments;

FIG. 17 is a cross-sectional view illustrating an example of a cross section of a display panel corresponding to the line 12-12′ of FIG. 16;

FIG. 18 is a detailed cross-sectional view of an embodiment of an area B1 of FIG. 17;

FIG. 19 is a cross-sectional view illustrating an example of a cross-section of a display panel corresponding to the line 12-12′ of FIG. 16;

FIG. 20 is a detailed cross-sectional view of an embodiment of an area B2 of FIG. 19;

FIG. 21 is a plan view of a light emitting element according to one or more embodiments;

FIG. 22 is a plan view of a light emitting element according to one or more embodiments;

FIG. 23 is a plan view of a light emitting element according to one or more embodiments;

FIG. 24 is a plan view of a light emitting element according to one or more embodiments;

FIG. 25 is a plan view of a light emitting element according to one or more embodiments;

FIG. 26 is a plan view of a light emitting element according to one or more embodiments;

FIG. 27 is a plan view of a light emitting element according to one or more embodiments;

FIG. 28 is a plan view of a light emitting element according to one or more embodiments;

FIG. 29 is a flowchart illustrating a method of manufacturing a display device according to one or more embodiments;

FIGS. 30 through 34 are cross-sectional views illustrating a method of manufacturing light emitting elements according to one or more embodiments;

FIG. 35 is a cross-sectional view illustrating a method of placing light emitting elements according to one or more embodiments;

FIG. 36 is a plan view of a patterned semiconductor substrate according to one or more embodiments;

FIG. 37 is a plan view of a semiconductor substrate on which light emitting elements are formed according to one or more embodiments;

FIGS. 38 through 42 are cross-sectional views illustrating a method of manufacturing light emitting elements according to one or more embodiments;

FIG. 43 is an example view of a smart watch including a display device according to one or more embodiments;

FIGS. 44 and 45 are example views of a virtual reality (VR) device including a display device according to one or more embodiments;

FIG. 46 is an example view of a VR device including a display device according to one or more embodiments;

FIG. 47 is an example view illustrating a vehicle instrument cluster and center fascia including display devices according to one or more embodiments; and

FIG. 48 is an example view of a transparent display device including a display device according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

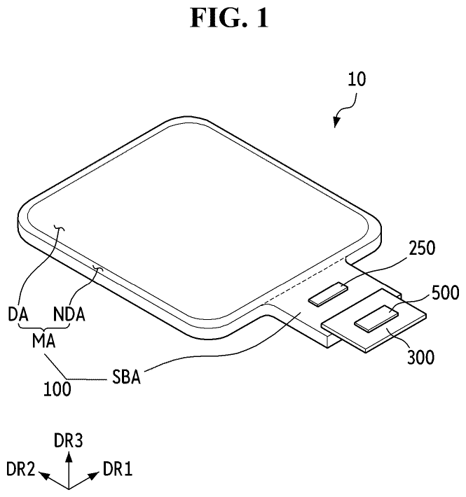

FIG. 1 is a perspective view of a display device 10 according to one or more embodiments.

Referring to FIG. 1, the display device 10 is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and/or Internet of things (IoT) devices.

The display device 10 may be a light emitting display device such as an organic light emitting display device using an organic light emitting diode (OLED), a quantum dot light emitting display device including a quantum dot light emitting layer, an inorganic light emitting display device including an inorganic semiconductor, or an ultrasmall light emitting display device using an ultrasmall light emitting diode (e.g., a micro-light emitting diode or a nano-light emitting diode). A case where the display device 10 is an ultrasmall light emitting display device will be mainly described below, but the present disclosure is not limited thereto. For ease of description, an ultrasmall light emitting diode will be referred to as a light emitting element.

The display device 10 includes a display panel 100, a display driving circuit 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape but may also be other polygonal shapes, a circular shape, or an elliptical shape. The display panel 100 may be formed flat, but the present disclosure is not limited thereto. For example, the display panel 100 may include a curved portion formed at left and right ends and having a constant or varying curvature. In addition, the display panel 100 may be formed to be flexible so that it can be curved, bent, folded, and/or rolled.

The display panel 100 may include a main area MA and a sub-area SBA.

The main area MA may include a display area DA which displays an image and a non-display area NDA disposed around the display area DA along an edge or a periphery of the display area DA. The display area DA may include a plurality of pixels that display an image. Each of the pixels may include a plurality of subpixels. For example, each of the pixels may include a first subpixel that emits light of a first color, a second subpixel that emits light of a second color, and a third subpixel that emits light of a third color, but the present disclosure is not limited thereto.

The sub-area SBA may protrude from a side of the main area MA in the second direction DR2. Although the sub-area SBA is unfolded in FIG. 1, it may be bent. In this case, the sub-area SBA may be placed on a lower surface of the display panel 100. When the sub-area SBA is bent, it may be overlapped by the main area MA in a third direction DR3 which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached onto the display panel 100 using a chip on glass (COG) method, a chip on plastic (COP) method, and/or an ultrasonic bonding method. However, the present disclosure is not limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film (COF).

The power supply unit 500 may generate a plurality of panel driving voltages according to a power supply voltage supplied from the outside. The power supply unit 500 may be formed as an integrated circuit (IC) and attached onto the circuit board 300 using a COF method.

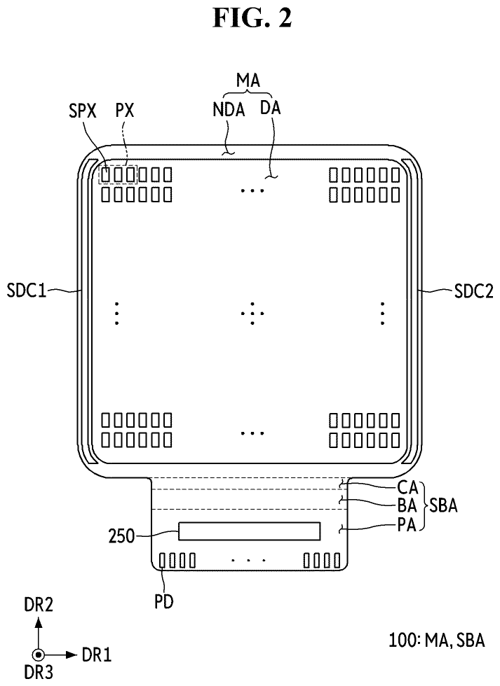

FIG. 2 is a layout view of the display device 10 according to one or more embodiments. FIG. 2 illustrates a state in which the sub-area SBA is unfolded.

Referring to FIG. 2, the display panel 100 may include the main area MA and the sub-area SBA.

The main area MA may include the display area DA which displays an image and the non-display area NDA disposed around the display area DA. The display area DA may occupy most of the main area MA. The display area DA may be disposed in the center of the main area MA.

The display area DA may include a plurality of pixels PX for displaying an image, and each of the pixels PX may include a plurality of subpixels SPX. A pixel PX may be defined as a smallest subpixel group that can express a white gray level.

The non-display area NDA may neighbor the display area DA. The non-display area NDA may be an area outside the display area DA. The non-display area NDA may surround the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, the present disclosure is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driving circuit 250 are disposed. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may contact the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may contact the connection area CA, and the other side of the bending area BA may contact the pad area PA.

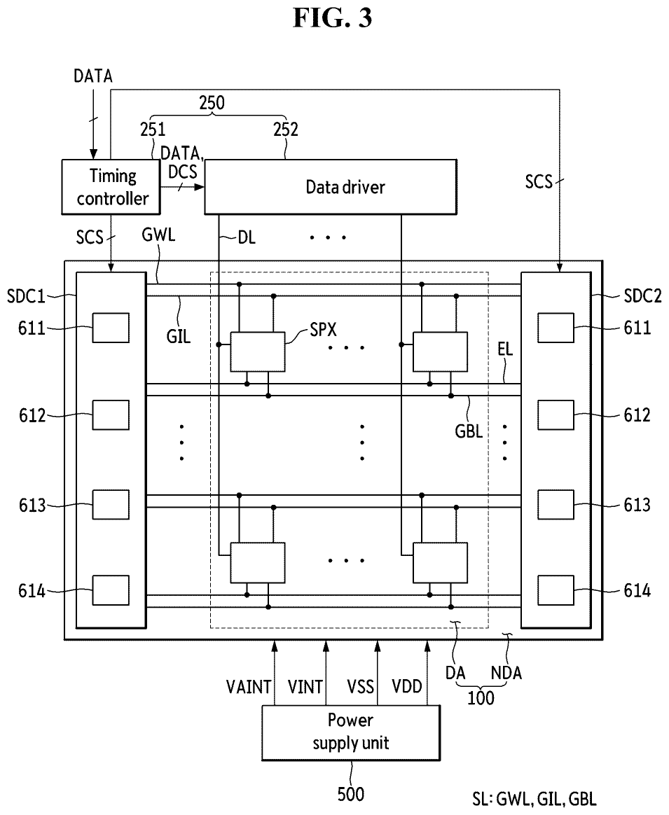

FIG. 3 is a block diagram of the display device 10 according to one or more embodiments.

Referring to FIG. 3, the display area DA includes a plurality of pixels PX, a plurality of scan lines SL, a plurality of emission control lines EL, and a plurality of data lines DL.

The pixels PX may be arranged in a matrix form along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. The scan lines SL may include a plurality of write scan lines GWL, a plurality of initialization scan lines GIL, and a plurality of bias scan lines GBL.

Each of a plurality of subpixels SPX may be connected to one of the write scan lines GWL, one of the initialization scan lines GIL, one of the bias scan lines GBL, one of the emission control lines EL, and one of the data lines DL. In the description of embodiments, “connection” may include direct connection or indirect connection and may include electrical and/or physical connection. Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, an initialization scan signal output unit 612, a bias scan signal output unit 613, and an emission control signal output unit 614. Each of the write scan signal output unit 611, the initialization scan signal output unit 612, the bias scan signal output unit 613, and the emission control signal output unit 614 may receive a scan timing control signal SCS from a timing controller 251.

The write scan signal output unit 611 may generate write scan signals according to the scan timing control signal SCS of the timing controller 251 and sequentially output the write scan signals to the write scan lines GWL.

The initialization scan signal output unit 612 may generate initialization scan signals according to the scan timing control signal SCS and sequentially output the initialization scan signals to the initialization scan lines GIL.

The bias scan signal output unit 613 may generate bias scan signals according to the scan timing control signal SCS and sequentially output the bias scan signals to the bias scan lines GBL.

The emission control signal output unit 614 may generate emission control signals according to the scan timing control signal SCS and sequentially output the emission control signals to the emission control lines EL.

The display driving circuit 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage supplied from the outside. For example, the power supply unit 500 may generate a first driving voltage VDD, a second driving voltage VSS, a third driving voltage VINT and a fourth driving voltage VAINT and supply them to the display panel 100.

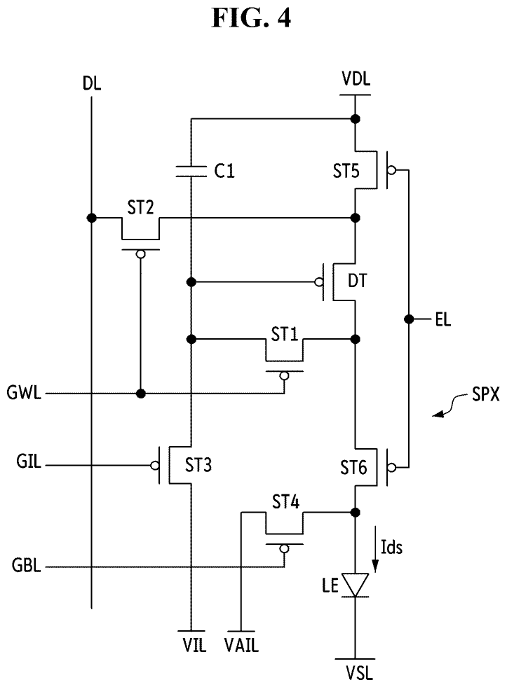

FIG. 4 is an equivalent circuit diagram of a subpixel SPX according to one or more embodiments.

Referring to FIG. 4, the subpixel SPX according to the embodiment may be connected to scan lines GWL, GIL and GBL, an emission control line EL, and a data line DL. For example, the subpixel SPX may be connected to a write scan line GWL, an initialization scan line GIL, a bias scan line GBL, the emission control line EL, and the data line DL.

The subpixel SPX according to the embodiment includes a driving transistor DT, switch elements, a capacitor C1, and a light emitting element LE. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode of the driving transistor DT according to a data voltage applied to the gate electrode of the driving transistor DT.

The light emitting element LE may be a micro-light emitting diode (LED).

The light emitting element LE emits light according to the driving current Ids. The amount of light emitted from the light emitting element LE may be proportional to the driving current Ids. An anode of the light emitting element LE may be connected to a first electrode of the fourth transistor ST4 and a second electrode of the sixth transistor ST6, and a cathode may be connected to a second power line VSL to which the second driving voltage VSS is applied.

The capacitor C1 is formed between the gate electrode of the driving transistor DT and a first power line VDL to which the first driving voltage VDD is applied. The first driving voltage VDD may be at a higher level than the second driving voltage VSS. One electrode of the capacitor C1 may be connected to the gate electrode of the driving transistor DT, and the other electrode may be connected to the first power line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and the gate electrodes of the fifth transistor ST5 and the sixth transistors ST6 may be connected to the emission control line EL. Because the first through sixth transistors ST1 through ST6 are formed as p-type MOSFETs, they may be turned on when a scan signal of a gate-low voltage and an emission control signal of a gate-low voltage are transmitted to the initialization scan line GIL, the write scan line GWL, the bias scan line GBL, and the emission control line EL. One electrode of the third transistor ST3 may be connected to a first initialization voltage line VIL to which the third driving voltage VINT (see FIG. 3) is applied, and one electrode of the fourth transistor ST4 may be connected to a second initialization voltage line VAIL to which the fourth driving voltage VAINT (see FIG. 3) is applied. The third driving voltage VINT (see FIG. 3) and the fourth driving voltage VAINT (see FIG. 3) may be different voltages. In addition, the third driving voltage VINT (see FIG. 3) and the fourth driving voltage VAINT (see FIG. 3) may be at a lower level than the first driving voltage VDD and at a higher level than the second driving voltage VSS.

Alternatively, the driving transistor DT, the second transistor ST2, the fourth transistor ST4, the fifth transistor ST5, and the sixth transistor ST6 may be formed as p-type MOSFETs, and the first transistor ST1 and the third transistor ST3 may be formed as n-type MOSFETs. In this case, the active layer of each of the driving transistor DT, the second transistor ST2, the fourth transistor ST4, the fifth transistor ST5, and the sixth transistor ST6 formed as p-type MOSFETs may be made of polysilicon, and the active layer of each of the first transistor ST1 and the third transistor ST3 formed as n-type MOSFETs may be made of an oxide semiconductor. In addition, because the first transistor ST1 and the third transistor ST3 are formed as n-type MOSFETs, the first transistor ST1 may be turned on in response to a write scan signal of a gate-high voltage, and the third transistor ST3 may be turned on in response to an initialization scan signal of a gate-high voltage. On the other hand, because the second transistor ST2, the fourth transistor ST4, the fifth transistor ST5, and the sixth transistor ST6 are formed as p-type MOSFETs, they may be turned on in response to a scan signal of a gate-low voltage and an emission control signal of a gate-low voltage.

Alternatively, the fourth transistor ST4 may be formed as an n-type MOSFET, and the other transistors DT, ST1, ST2, ST3, ST5, and ST6 may be formed as p-type MOSFETs. In this case, the active layer of the fourth transistor ST4 may be made of an oxide semiconductor, and the active layer of each of the other transistors DT, ST1, ST2, ST3, ST5, and ST6 may be made of polysilicon. In addition, while the fourth transistor ST4 is turned in response to a scan signal of a gate-high voltage, the other transistors DT, ST1, ST2, ST3, ST5, and ST6 may be turned on in response to a scan signal of a gate-low voltage and an emission control signal of a gate-low voltage.

Alternatively, the first through sixth transistors ST1 through ST6 and the driving transistor DT may all be formed as n-type MOSFETs. In this case, the active layer of each of the first through sixth transistors ST1 through ST6 and the driving transistor DT may be made of an oxide semiconductor, and the first through sixth transistors ST1 through ST6 and the driving transistor DT may be turned on in response to a scan signal of a gate-high voltage and an emission control signal of a gate-high voltage.

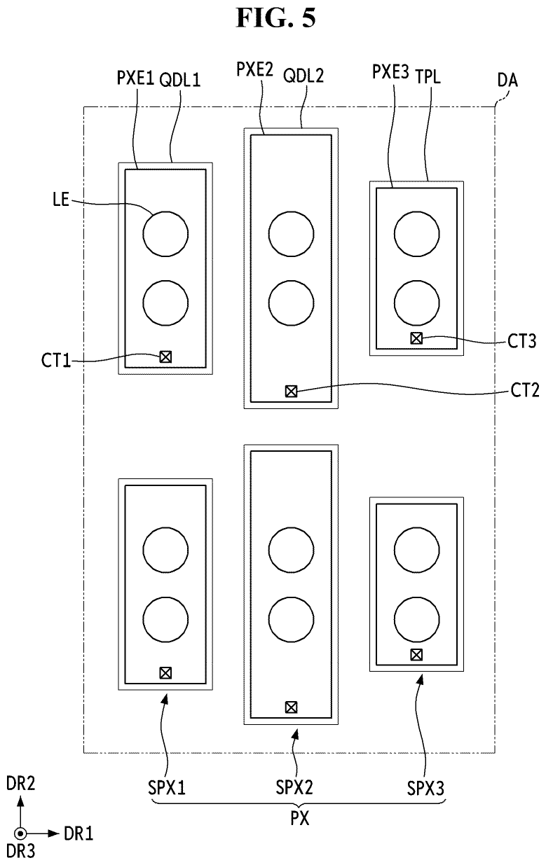

FIG. 5 is a layout view illustrating pixels PX of a display area DA according to one or more embodiments.

Referring to FIG. 5, each of the pixels PX in the display area DA may include three subpixels SPX1 through SPX3. However, the present disclosure is not limited thereto, and each of the pixels PX may also include four subpixels. When each of the pixels PX includes three subpixels SPX1 through SPX3, it may include a first subpixel SPX1, a second subpixel SPX2, and a third subpixel SPX3.

The pixels PX may be arranged in a matrix form. In each of the pixels PX, the first subpixel SPX1, the second subpixel SPX2, and the third subpixel SPX3 may be arranged along the first direction DR1.

When each of the pixels PX includes three subpixels SPX1 through SPX3, the first subpixel SPX1 may output light of a first color, the second subpixel SPX2 may output light of a second color, and the third subpixel SPX3 may output light of a third color. Here, the light of the first color may be light in a red wavelength band, the light of the second color may be light in a green wavelength band, and the light of the third color may be light in a blue wavelength band. For example, the red wavelength band may indicate that a main peak wavelength of light is included in a wavelength band of about 600 to 750 nm, the green wavelength band may indicate that a main peak wavelength of light is included in a wavelength band of about 480 to 560 nm, and the blue wavelength band may indicate that a main peak wavelength of light is included in a wavelength band of about 370 to 460 nm.

Alternatively, when each of the pixels PX includes four subpixels, a first subpixel may output light of the first color, a second subpixel and a fourth subpixel may output light of the second color, and a third subpixel may output light of the third color. Alternatively, the first subpixel may output light of the first color, the second subpixel may output light of the second color, the third subpixel may output light of the third color, and the fourth subpixel may output light of a fourth color. Here, the light of the fourth color may be white light.

The first subpixel SPX1 includes a first pixel electrode PXE1, a plurality of light emitting elements LE, and a first light conversion layer QDL1. The second subpixel SPX2 includes a second pixel electrode PXE2, a plurality of light emitting elements LE, and a second light conversion layer QDL2. The third subpixel SPX3 includes a third pixel electrode PXE3, a plurality of light emitting elements LE, and a light transmission layer (or a third light conversion layer) TPL.

Each of the first pixel electrode PXE1, the second pixel electrode PXE2, and the third pixel electrode PXE3 may be shaped like a rectangular plane having short sides in the first direction DR1 and long sides in the second direction DR2. The area of the first subpixel SPX1, the area of the second subpixel SPX2, and the area of the third subpixel SPX3 may be set according to the light conversion efficiency of the first light conversion layer QDL1 and the light conversion efficiency of the second light conversion layer QDL2. For example, the lower the light conversion efficiency, the larger the area of a subpixel.

For example, as illustrated in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1. In addition, because the first light conversion layer QDL1 must convert light whereas the light transmission layer TPL transmits light of a light emitting element LE as it is, the area of the first pixel electrode PXE1 may be larger than the area of the third pixel electrode PXE3.

Each of the pixel electrodes PXE1 through PXE3 may be electrically connected to at least one transistor through a pixel connection hole CT1/CT2/CT3. For example, each of the pixel electrodes PXE1 through PXE3 may be electrically connected to a first electrode of the fourth transistor ST4 (see FIG. 4) and the second electrode of the sixth transistor ST6 (see FIG. 4) of a corresponding subpixel.

A plurality of light emitting elements LE may be disposed on each of the pixel electrodes PXE1 through PXE3. The same number of light emitting elements LE may be disposed on each of the pixel electrodes PXE1 through PXE3. For example, two light emitting elements LE may be disposed on each of the pixel electrodes PXE1 through PXE3. The light emitting elements LE may emit light of the third color, for example, light in the blue wavelength band, but the present disclosure is not limited thereto. If the light emitting elements LE of the first subpixel SPX1 emit light of the first color, the light emitting elements LE of the second subpixel SPX2 emit light of the second color, and the light emitting elements LE of the third subpixel SPX3 emit light of the third color, the light conversion layers QDL1 and QDL2 and the light transmission layer TPL may be omitted.

The first light conversion layer QDL1 may completely overlap the first pixel electrode PXE1 and the light emitting elements LE of the first subpixel SPX1. The area of the first light conversion layer QDL1 may be larger than the area of the first pixel electrode PXE1. The first light conversion layer QDL1 may convert or shift a peak wavelength of incident light into another specific peak wavelength and output light of the specific peak wavelength. For example, the first light conversion layer QDL1 may convert or shift third light emitted from the light emitting elements LE of the first subpixel SPX1 into first light.

The second light conversion layer QDL2 may completely overlap the second pixel electrode PXE2 and the light emitting elements LE of the second subpixel SPX2. The area of the second light conversion layer QDL2 may be larger than the area of the second pixel electrode PXE2. The second light conversion layer QDL2 may convert or shift a peak wavelength of incident light into another specific peak wavelength and output light of the specific peak wavelength. For example, the second light conversion layer QDL2 may convert or shift third light emitted from the light emitting elements LE of the second subpixel SPX2 into second light.

The light transmission layer TPL may completely overlap the third pixel electrode PXE3 and the light emitting elements LE of the third subpixel SPX3. The light transmission layer TPL may transmit incident light as it is. For example, the light transmission layer TPL may transmit third light emitted from the light emitting elements LE of the third subpixel SPX3 as it is.

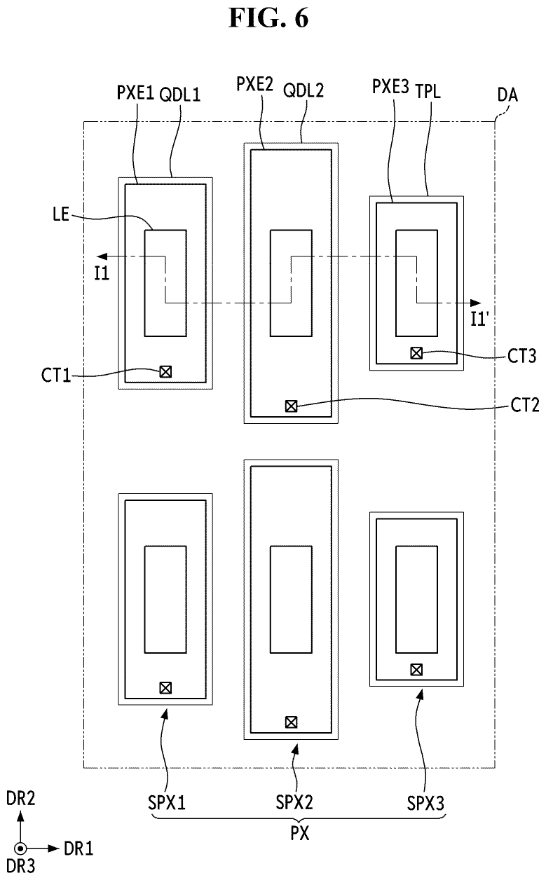

FIG. 6 is a layout view illustrating pixels PX of a display area DA according to one or more embodiments. FIG. 6 shows an embodiment different from the embodiment of FIG. 4 in relation to light emitting elements LE disposed in subpixels SPX1 through SPX3.

Referring to FIG. 6, a subpixel SPX may include a single light emitting element LE disposed on each pixel electrode PXE1/PXE2/PXE3. In one or more embodiments, the light emitting element LE may have a shape corresponding to the shape of each pixel electrode PXE1/PXE2/PXE3, for example, a quadrangular planar shape. For example, the light emitting element LE may have a rectangular planar shape which is longer in a direction in which long sides of the pixel electrodes PXE1 through PXE3 extend, for example, the second direction DR2 than in the first direction DR1.

However, the shape of the light emitting element LE is not limited thereto. For example, the light emitting element LE may also have a circular planar shape as illustrated in FIG. 5 or may have a planar shape other than the circular shape and the quadrangular shape.

The light emitting element LE may have a size that allows it to be appropriately or stably disposed inside each pixel electrode PXE1/PXE2/PXE3 or inside an emission area in which the pixel electrode PXE1/PXE2/PXE3 is disposed. The emission area of each of the subpixels SPX1 through SPX3 may be an area where the pixel electrode PXE1/PXE2/PXE3 and the light emitting element LE of each of the subpixels SPX1 through SPX3 are disposed and may be a light transmitting area where light generated from the light emitting element LE is emitted.

The type, number, shape, and/or size of light emitting elements LE that can be disposed in each of the subpixels SPX1 through SPX3 is not limited to the embodiments of FIGS. 5 and 6. For example, each of the subpixels SPX1 through SPX3 may also include various types, numbers, shapes, and/or sizes of light emitting elements LE according to one or more embodiments. In addition, the subpixels SPX1 through SPX3 may include the same or different numbers of light emitting elements LE.

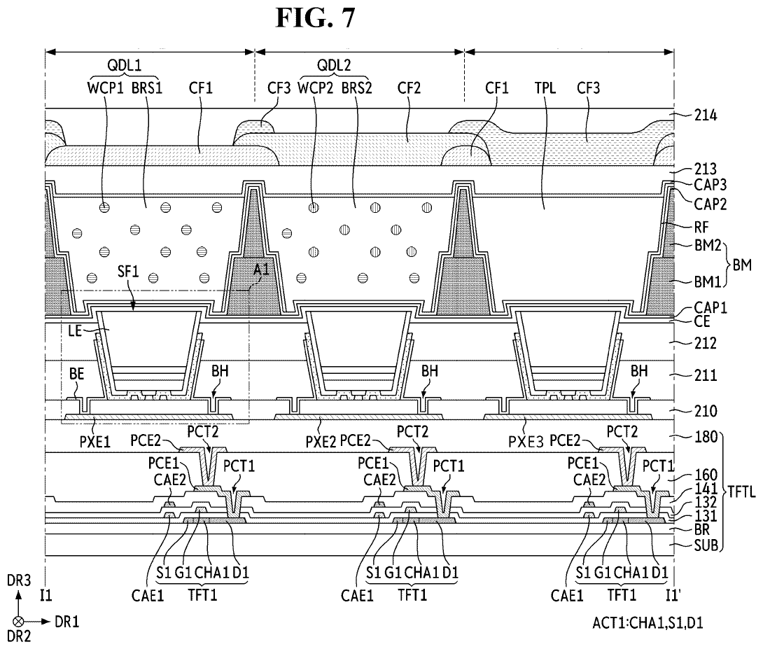

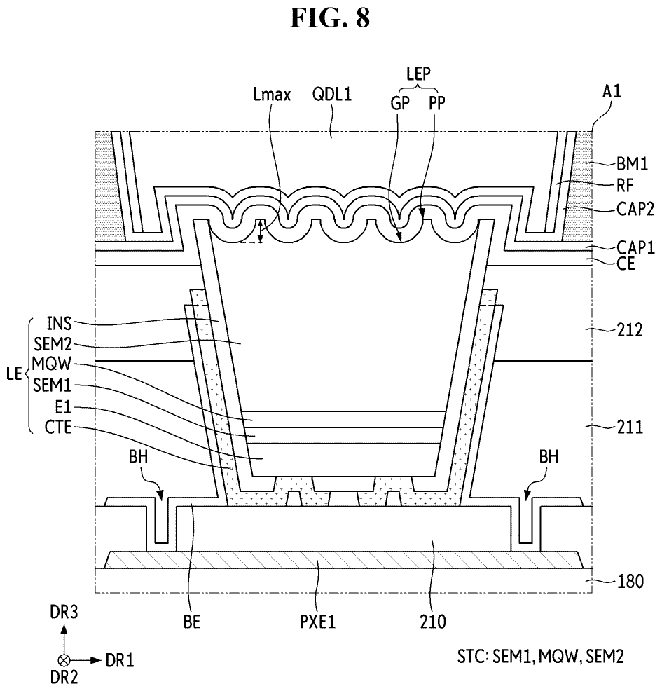

FIG. 7 is a cross-sectional view illustrating an example of a cross section of a display panel 100 corresponding to the line 11-11′ of FIG. 6. FIG. 8 is a detailed cross-sectional view of an embodiment of an area A1 of FIG. 7.

Referring to FIGS. 7 and 8, the display panel 100 may include a thin-film transistor layer TFTL, pixel electrodes PXE1 through PXE3 disposed on the thin-film transistor layer TFTL, light emitting elements LE disposed on the pixel electrodes PXE1 through PXE3, and light conversion layers QDL1 and QDL2, a light transmission layer TPL and color filters CF1 through CF3 disposed on the light emitting elements LE.

The thin-film transistor layer TFTL may include a substrate SUB and circuit elements and lines disposed on the substrate SUB. In FIG. 7, the substrate SUB is considered as an element included in the thin-film transistor layer TFTL. However, the present disclosure is not limited thereto. For example, the substrate SUB and the thin-film transistor layer TFTL may also be considered as separate elements, and the thin-film transistor layer TFTL may be viewed as being disposed on the substrate SUB. In FIG. 7, one thin-film transistor TFT1 included in each subpixel SPX is illustrated as representing the circuit elements of the thin-film transistor layer TFTL (e.g., circuit elements of a pixel circuit included in each of the subpixels SPX1 through SPX3).

The substrate SUB may be made of an insulating material such as glass and/or polymer resin. When the substrate SUB is made of polymer resin, it may be a flexible substrate that can be stretched. The polymer resin may be acryl resin, epoxy resin, phenolic resin, polyamide resin, and/or polyimide resin.

A barrier layer BR may be disposed on the substrate SUB. The barrier layer BR is a layer for protecting transistors of the thin-film transistor layer TFTL and the light emitting elements LE on the thin-film transistor layer TFTL from moisture introduced through the substrate SUB which is vulnerable to moisture penetration. The barrier layer BR may be composed of a plurality of inorganic layers stacked alternately.

Thin-film transistors TFT1 may be disposed on the barrier layer BR. Each of the thin-film transistors TFT1 illustrated in FIG. 7 may be one of the fourth transistor ST4 and the sixth transistor ST6 illustrated in FIG. 4. Each of the thin-film transistors TFT1 may include a first active layer ACT1 and a first gate electrode G1.

The first active layer ACT1 of each of the thin-film transistors TFT1 may be disposed on the barrier layer BR. The first active layer ACT1 of each of the thin-film transistors TFT1 may include polycrystalline silicon, monocrystalline silicon, low-temperature polycrystalline silicon, and/or amorphous silicon. Alternatively, the first active layer ACT1 of each of the thin-film transistors TFT1 may be made of an oxide semiconductor including IGZO (indium (In), gallium (Ga), zinc (Zn) and oxygen (O)), IGZTO (indium (In), gallium (Ga), zinc (Zn), tin (Sn) and oxygen (O)), or IGTO (indium (In), gallium (Ga), tin (Sn) and oxygen (O)).

The first active layer ACT1 may include a first channel region CHA1, a first source region S1, and a first drain region D1. The first channel region CHA1 may be a region overlapped by the first gate electrode G1 in the third direction DR3 which is the thickness direction of the substrate SUB. The first source region S1 may be disposed on a side of the first channel region CHA1, and the first drain region D1 may be disposed on the other side of the first channel region CHA1. The first source region S1 and the first drain region D1 may be regions not overlapped by the first gate electrode G1 in the third direction DR3. The first source region S1 and the first drain region D1 may be regions formed to have conductivity by doping a semiconductor material with ions.

A first gate insulating layer 131 may be disposed on the first channel regions CHA1, the first source regions S1, and the first drain regions D1 of the thin-film transistors TFT1 and the barrier layer BR.

A first gate metal layer may be disposed on the first gate insulating layer 131. The first gate metal layer may include the first gate electrodes G1 of the thin-film transistors TFT1 and first capacitor electrodes CAE1. The first gate electrodes G1 may overlap the first active layers ACT1 in the third direction DR3. In FIG. 7, the first gate electrodes G1 and the first capacitor electrodes CAE1 are spaced (e.g., spaced apart) from each other. However, when each of the thin-film transistors TFT1 is the driving transistor DT of FIG. 4, the first gate electrodes G1 and the first capacitor electrodes CAE1 may also be electrically or physically connected to each other. Alternatively, when each of the thin-film transistors TFT1 is one of the first through sixth transistors ST1 through ST6 of FIG. 4, the first gate electrodes G1 and the first capacitor electrodes CAE1 may not be electrically or physically connected to each other.

A second gate insulating layer 132 may be disposed on the first gate electrodes G1 of the thin-film transistors TFT1 and the first capacitor electrodes CAE1, and on the first gate insulating layer 131.

A second gate metal layer may be disposed on the second gate insulating layer 132. The second gate metal layer may include second capacitor electrodes CAE2. The second capacitor electrodes CAE2 may overlap the first capacitor electrodes CAE1 in the third direction DR3. Because the second gate insulating layer 132 has a suitable dielectric constant (e.g., a predetermined dielectric constant), capacitors C1 (see FIG. 4) may be formed by the first capacitor electrodes CAE1, the second capacitor electrodes CAE2, and the second gate insulating layer 132 disposed between them.

An interlayer insulating layer 141 may be disposed on the second capacitor electrodes CAE2 and on the second gate insulating layer 132.

A first data metal layer may be disposed on the interlayer insulating layer 141. The first data metal layer may include first source connection electrodes PCE1. The first source connection electrodes PCE1 may be connected to the first drain regions D1 of the first active layers ACT1 through first source contact holes PCT1 penetrating the first gate insulating layer 131, the second gate insulating layer 132, and the interlayer insulating layer 141.

A first planarization layer 160 may be disposed on the first source connection electrodes PCE1 and the interlayer insulating layer 141 to flatten steps caused by the thin-film transistors TFT1.

A second data metal layer may be disposed on the first planarization layer 160. The second data metal layer may include second source connection electrodes PCE2. The second source connection electrodes PCE2 may be connected to the first source connection electrodes PCE1 through second source contact holes PCT2 penetrating the first planarization layer 160.

A second planarization layer 180 may be disposed on the second source connection electrodes PCE2 and the first planarization layer 160.

The barrier layer BR, the first gate insulating layer 131, the second gate insulating layer 132, and the interlayer insulating layer 141 may be made of an inorganic layer, for example, silicon nitride (SiNₓ), silicon oxynitride (SiON), silicon oxide (SiOₓ), titanium oxide (TiOₓ), and/or aluminum oxide (AlOₓ).

The first gate metal layer, the second gate metal layer, the first data metal layer, and the second data metal layer may each be a single layer or a multilayer made of molybdenum (Mo), aluminum (Al), chromium (Cr), gold (Au), titanium (Ti), nickel (Ni), neodymium (Nd), copper (Cu), and/or alloys thereof.

The first planarization layer 160 and the second planarization layer 180 may be made of an organic layer such as acryl resin, epoxy resin, phenolic resin, polyamide resin, and/or polyimide resin.

A light emitting element layer may be disposed on the second planarization layer 180. The light emitting element layer may include the pixel electrodes PXE1 through PXE3, the light emitting elements LE, a common electrode CE, and organic layers 210, 211 and 212.

A pixel electrode layer may be disposed on the second planarization layer 180. The pixel electrode layer may include a first pixel electrode PXE1, a second pixel electrode PXE2, and a third pixel electrode PXE3. Each of the pixel electrodes PXE1 through PXE3 may be connected to a second source connection electrode PCE2 through a pixel connection hole CT1/CT2/CT3 (see FIG. 6) penetrating the second planarization layer 180. Each of the pixel electrodes PXE1 through PXE3 may be connected to the first source region S1 or the first drain region D1 of a thin-film transistor TFT1 through a first source connection electrode PCE1 and a second source connection electrode PCE2. Therefore, a voltage controlled by a thin-film transistor TFT1 may be applied to each of the pixel electrodes PXE1 through PXE3.

The pixel electrode layer may be a single layer or a multilayer made of molybdenum (Mo), aluminum (Al), chromium (Cr), gold (Au), titanium (Ti), nickel (Ni), neodymium (Nd), copper (Cu), and/or alloys thereof. For example, the pixel electrode layer may be made of copper (Cu) with low sheet resistance in order to lower the resistance of each of the pixel electrodes PXE1 through PXE3.

A first organic layer 210 may be disposed on each of the pixel electrodes PXE1 through PXE3. The first organic layer 210 temporarily fixes or attaches a plurality of light emitting elements LE to prevent the light emitting elements LE from tilting or falling during a process of transferring the light emitting elements LE to the display panel 100. That is, the first organic layer 210 may be a layer for temporarily attaching the light emitting elements LE onto the pixel electrodes PXE1 through PXE3, respectively. To facilitate the temporary adhesion, the first organic layer 210 may be thicker than each of the pixel electrodes PXE1 through PXE3 and thicker than contact electrodes CTE.

The first organic layer 210 may be a photosensitive organic layer such as photoresist. Alternatively, the first organic layer 210 may be made of acryl resin, epoxy resin, phenolic resin, polyamide resin, and/or polyimide resin.

The light emitting elements LE may be disposed on the first organic layer 210. In FIG. 6, each of the light emitting elements LE is a vertical type micro-LED extending in the third direction DR3. The vertical type micro-LED refers to an LED having a structure in which a first semiconductor layer SEM1, an active layer MQW, and a second semiconductor layer SEM2 are sequentially disposed in the third direction DR3, which is a vertical direction.

Each of the light emitting elements LE may have a reverse-tapered cross-sectional shape. For example, each of the light emitting elements LE may have a trapezoidal cross-sectional shape whose upper surface is wider than a lower surface.

Each of the light emitting elements LE may be made of an inorganic material such as gallium nitride (GaN). Each of the light emitting elements LE may have a length of several to hundreds of μm in each of the first direction DR1, the second direction DR2, and the third direction DR3. For example, each of the light emitting elements LE may have a length of about 100 μm or less in each of the first direction DR1, the second direction DR2, and the third direction DR3. However, a size of each of the light emitting elements LE may vary according to one or more embodiments.

Each of the light emitting elements LE may be grown on a semiconductor substrate such as a silicon substrate and/or a sapphire substrate. The light emitting elements LE may be transferred from the semiconductor substrate onto the pixel electrodes PXE1 through PXE3 of the display panel 100 directly or via a relay substrate. Alternatively, the light emitting elements LE may be transferred onto the pixel electrodes PXE1 through PXE3 of the display panel 100 through an electrostatic method using an electrostatic head and/or a stamp method using an elastic polymer material, such as PDMS and/or silicon, as a transfer substrate.

Each of the light emitting elements LE may include at least a semiconductor stack STC. For example, each of the light emitting elements LE may include a conductive layer E1, a semiconductor stack STC, contact electrodes CTE, and a protective layer INS. The semiconductor stack STC may include a first semiconductor layer SEM1, an active layer MQW, and a second semiconductor layer SEM2 sequentially disposed in the third direction DR3.

The conductive layer E1 may be disposed on a lower surface of the first semiconductor layer SEM1. Although the conductive layer E1 covers the entire lower surface of the first semiconductor layer SEM1 in FIG. 8, the present disclosure is not limited thereto. For example, the conductive layer E1 may also be disposed on a portion of the lower surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the conductive layer E1. The first semiconductor layer SEM1 may be made of a semiconductor material layer, for example, gallium nitride (GaN) doped with a first conductivity type dopant such as magnesium (Mg), zinc (Zn), calcium (Ca), strontium (Sr), and/or barium (Ba).

The active layer MQW may be disposed on the first semiconductor layer SEM1. The active layer MQW may include the same semiconductor material layer as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include gallium nitride (GaN), indium gallium nitride (InGaN), and/or aluminum gallium nitride (AlGaN). The active layer MQW may emit light through combination of electron-hole pairs according to electrical signals received through the first semiconductor layer SEM1 and the second semiconductor layer SEM2.

The active layer MQW may include a material having a single or multiple quantum well structure. When the active layer MQW includes a material having a multiple quantum well structure, it may be a structure in which a plurality of well layers and a plurality of barrier layers are alternately stacked. Here, the well layers may be made of InGaN, and the barrier layers may be made of GaN or AlGaN, but the present disclosure is not limited thereto. Alternatively, the active layer MQW may be a structure in which a semiconductor material having a large band gap energy and a semiconductor material having a small band gap energy are alternately stacked or may include different group Ill to V semiconductor materials depending on the wavelength band of light that it emits.

When the active layer MQW includes indium gallium nitride (InGaN), the color of light that it emits may vary according to indium content. For example, as the indium content increases, the wavelength band of light emitted from the active layer MQW may move to the red wavelength band, and as the indium content decreases, the wavelength band of light emitted from the active layer MQW may move to the blue wavelength band. For example, the indium content of the active layer MQW of a light emitting element LE that emits third light (e.g., light in the blue wavelength band) may be about 10 to 20 wt %.

The second semiconductor layer SEM2 may be disposed on the active layer MQW. The second semiconductor layer SEM2 may be made of a semiconductor material layer, for example, gallium nitride (GaN) doped with a second conductivity type dopant such as silicon (Si), germanium (Ge), and/or tin (Sn).

An electron blocking layer may be disposed between the first semiconductor layer SEM1 and the active layer MQW. The electron blocking layer may be a layer for suppressing or preventing too many electrons from flowing into the active layer MQW. For example, the electron blocking layer may be AlGaN or p-AlGaN doped with p-type Mg. The electron blocking layer can be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be made of InGaN and/or GaN. The superlattice layer can be omitted.

The protective layer INS may cover side surfaces of the semiconductor stack STC and may cover side surfaces and a bottom surface of the conductive layer E1. For example, the protective layer INS may be disposed on side surfaces of the first semiconductor layer SEM1, side surfaces of the active layer MQW, and side surfaces of the second semiconductor layer SEM2. The protective layer INS may be a layer for protecting side surfaces of each light emitting element LE. The protective layer INS may be made of an inorganic layer, for example, silicon nitride (SiNₓ), silicon oxynitride (SiON), silicon oxide (SiOₓ), titanium oxide (TiOₓ), and/or aluminum oxide (AlOₓ). In one or more embodiments, the protective layer INS may also be disposed on lower and side surfaces of the conductive layer E1.

The contact electrodes CTE may be disposed on the protective layer INS. The contact electrodes CTE may be disposed between the first organic layer 210 and the protective layer INS. The contact electrodes CTE may contact the first organic layer 210.

In one or more embodiments, a plurality of contact electrodes CTE may be disposed on the protective layer INS. Each of the contact electrodes CTE may be disposed between the first organic layer 210 and the protective layer INS. Each of the contact electrodes CTE may contact the first organic layer 210.

Although the contact electrodes CTE of each of the light emitting elements LE are disposed on the first organic layer 210 in FIGS. 7 and 8, the present disclosure is not limited thereto. For example, the first organic layer 210 may be disposed on a lower surface and a portion of a side surface of each of the contact electrodes CTE of each of the light emitting elements LE. Alternatively, the first organic layer 210 may be disposed on the side surfaces of the conductive layer E1 of each of the light emitting elements LE. Alternatively, the first organic layer 210 may be disposed on the side surfaces of the first semiconductor layer SEM1, the side surfaces of the active layer MQW, and the side surfaces of the second semiconductor layer SEM2 of each of the light emitting elements LE. In this case, the first organic layer 210 may be disposed on a portion of each side surface of the second semiconductor layer SEM2.

The contact electrodes CTE may be connected to the conductive layer E1 exposed without being covered by the protective layer INS. Accordingly, even if one of the contact electrodes CTE is not connected to the conductive layer E1 due to a process error, the other contact electrode CTE may be connected to the conductive layer E1, thereby preventing a light emitting element LE from not lighting up.

When the contact electrodes CTE are made of a metal with high reflectivity, light travelling in a lateral direction of the light emitting element LE from among light emitted from the active layer MQW of the light emitting element LE may be reflected by the contact electrodes CTE to exit from an upper surface of the light emitting element LE. Accordingly, a loss of light of the light emitting element LE can be reduced, and thus the light efficiency of the light emitting element LE can be increased. Therefore, in order to increase the light efficiency of the light emitting element LE, the contact electrodes CTE may cover most of the side surfaces of the semiconductor stack STC.

The contact electrodes CTE may include molybdenum (Mo), aluminum (Al), chromium (Cr), gold (Au), titanium (Ti), nickel (Ni), neodymium (Nd), and/or copper (Cu). Specifically, to increase reflectivity, the contact electrodes CTE may have a two-layer structure of chromium (Cr) and gold (Au), a three-layer structure of titanium (Ti), aluminum (Al) and titanium (Ti), or a three-layer structure of indium tin oxide (ITO), silver (Ag) and indium tin oxide (ITO).

Connection electrodes BE connect the contact electrodes CTE of each light emitting element LE to one of the pixel electrodes PXE1 through PXE3. The connection electrodes BE may be connected to one of the pixel electrodes PXE1 through PXE3 exposed through connection holes BH penetrating the first organic layer 210. In addition, the connection electrodes BE may be disposed on an upper surface of the first organic layer 210 and the side surfaces of the contact electrodes CTE. In addition, the connection electrodes BE may be disposed on a portion of the side surfaces of each light emitting element LE. For example, the connection electrodes BE may be disposed on a portion of the protective layer INS of each light emitting element LE.

The connection electrodes BE may include molybdenum (Mo), aluminum (Al), chromium (Cr), gold (Au), titanium (Ti), nickel (Ni), neodymium (Nd), and/or copper (Cu). Alternatively, the connection electrodes BE may be made of a transparent conductive material (TCO) that can transmit light, such as indium tin oxide (ITO) and/or indium zinc oxide (IZO).

When the connection electrodes BE are made of a metal material with high reflectivity such as aluminum (Al), light travelling in the lateral direction of a light emitting element LE from among light emitted from the active layer MQW of the light emitting element LE may be reflected by the connection electrodes BE toward the top of the light emitting element LE. Accordingly, a loss of light of the light emitting element LE can be reduced, and thus the light efficiency of the light emitting element LE can be increased.

In one or more embodiments, each light emitting element LE may include a patterned light output surface. For example, each light emitting element LE may include light extraction patterns LEP disposed on a light output surface of the semiconductor stack STC as illustrated in FIG. 8.

In one or more embodiments, the light output surface of the semiconductor stack STC may be an upper surface of the semiconductor stack STC, for example, an upper surface of the second semiconductor layer SEM2. For example, the light extraction patterns LEP may be formed on the upper surface of the second semiconductor layer SEM2.

In one or more embodiments, the light extraction patterns LEP may be formed by etching the semiconductor stack STC and may be formed integrally with the semiconductor stack STC. In this case, the light extraction patterns LEP may be considered as a part of the semiconductor stack STC. For example, if the light extraction patterns LEP are formed by etching the second semiconductor layer SEM2, they may be considered as a part of the second semiconductor layer SEM2.

The light extraction patterns LEP may be patterns for increasing the emission efficiency of light that passes through the light output surface of each light emitting element LE. For example, the light extraction patterns LEP may be micro-patterns formed to have depressions and elevations on the light output surface of each light emitting element LE and may be formed in the form of a micro-lens array, a diffuse reflection structure, or a diffuse refractive surface. As long as the light extraction patterns LEP can have a shape or structure that can improve the light output efficiency of each light emitting element LE, the shape, structure, size, etc. of the light extraction patterns LEP are not particularly limited. For example, the light extraction patterns LEP may be formed on the light output surface of each light emitting element LE to include regular or irregular curves or bumps and may have various shapes and/or sizes according to one or more embodiments.

In one or more embodiments, the light extraction patterns LEP may include groove portions GP (e.g., portions including respective valleys of the light extraction patterns LEP), which are repeated along at least one of the first direction DR1 and the second direction DR2, and protrusion portions PP (e.g., portions including respective peaks of the light extraction patterns LEP) disposed around a periphery or a circumference of or around the groove portions GP. The protrusion portion PP of each of the light extraction patterns LEP may surround a groove portion GP. The groove portions GP and the protrusion portions PP of the light extraction patterns LEP may be regularly and/or periodically repeated in at least one direction, but the present disclosure is not limited thereto.

In one or more embodiments, the light extraction patterns LEP may include a plurality of groove portions GP having a hemispherical or semi-ellipsoidal shape and protrusion portions PP disposed around the groove portions GP. For example, the light extraction patterns LEP may include a plurality of groove portions GP having a semicircular or semi-elliptical cross-sectional shape and protrusion portions PP disposed around the periphery or the circumference of the groove portions GP.

In one or more embodiments, a maximum length Lmax of each light extraction patterns LEP in the third direction DR3 may be about several microns or less. In addition, the light extraction patterns LEP may be formed at a distance sufficiently spaced (e.g., spaced apart) from the active layer MQW. For example, the maximum length Lmax of each light extraction pattern LEP in the third direction DR3 may be equal to or less than half of a thickness of the second semiconductor layer SEM2 (e.g., a length of the second semiconductor layer SEM2 in the third direction DR3). However, the present disclosure is not limited thereto. The size, shape, number, and/or arrangement interval of the light extraction patterns LEP may be appropriately set or changed in consideration of the size, shape, structure, light output efficiency, and/or stability of each light emitting element LE.

Because each light emitting element LE includes the light extraction patterns LEP formed on the light output surface thereof, the light output efficiency of the light emitting element LE and a subpixel SPX including the light emitting element LE can be improved.

In one or more embodiments, a semiconductor substrate for manufacturing the light emitting elements LE may be patterned to form patterns, which correspond to the light extraction patterns LEP, on a surface of the semiconductor substrate, and semiconductor material layers for forming the second semiconductor layer SEM2, the active layer MQW, and the first semiconductor layer SEM1 may sequentially formed (e.g., grown) on the patterned semiconductor substrate and then etched to manufacture the light emitting elements LE. Accordingly, each light emitting element LE may include the light extraction patterns LEP on a surface on which the second semiconductor layer SEM2 is disposed. In addition, each light emitting element LE may be placed on a pixel electrode PXE1/PXE2/PXE3 such that the light output surface of the light emitting element LE having the light extraction patterns LEP faces upward.

The shape or size of the light extraction patterns LEP included in each light emitting element LE or a method or operation for forming the light extraction patterns LEP may vary according to embodiments. For example, in one or more embodiments, a patterning process for forming the light extraction patterns LEP may be additionally performed after the manufacture of the light emitting elements LE to form the light extraction patterns LEP on the light output surface (e.g., the upper surface) of each light emitting element LE.

In one or more embodiments, the light emitting elements LE of the subpixels SPX1 through SPX3 may include the light extraction patterns LEP of the same shape. For example, the light extraction patterns LEP of the light emitting elements LE disposed on the pixel electrodes PXE1 through PXE3 may be arranged in the same structure on the light output surfaces of the light emitting elements LE. In addition, the light emitting elements LE may include the same number of light extraction patterns LEP. Accordingly, the light output characteristics of the light emitting elements LE and the subpixels SPX1 through SPX3 including the light emitting elements LE can be made uniform.

A second organic layer 211 may partially cover the side surfaces of the light emitting elements LE. In addition, the second organic layer 211 may cover the connection electrodes BE, but at least a portion of each of the connection electrodes BE may be exposed without being covered by the second organic layer 211.

A third organic layer 212 may be disposed on the second organic layer 211. The third organic layer 212 may partially cover the side surfaces of each of the light emitting elements LE. The third organic layer 212 may be disposed on at least a portion of each of the connection electrodes BE exposed without being covered by the second organic layer 211. The upper surface of each of the light emitting elements LE may be exposed without being covered by the third organic layer 212.

The second organic layer 211 and the third organic layer 212 may be made of an organic layer such as acryl resin, epoxy resin, phenolic resin, polyamide resin, and/or polyimide resin.

The second organic layer 211 and the third organic layer 212 are layers for flattening steps caused by the light emitting elements LE. If the second organic layer 211 is high enough to cover most of the side surfaces of each of the light emitting elements LE, the third organic layer 212 may be omitted.

The common electrode CE may be disposed on the upper surface of each of the light emitting elements LE and an upper surface of the third organic layer 212. The common electrode CE may be a common layer commonly formed in a first subpixel SPX1, a second subpixel SPX2, and a third subpixel SPX3. The common electrode CE may be made of a transparent conductive material (TCO) that can transmit light, such as indium tin oxide (ITO) and/or indium zinc oxide (IZO).

The pixel electrodes PXE1 through PXE3 may be referred to as anodes or first electrodes, and the common electrode CE may be referred to as a cathode or a second electrode.

A first capping layer CAP1 may be disposed on the common electrode CE.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be separated by the light blocking layer BM. Therefore, the first light conversion layer QDL1 may be disposed on the first capping layer CAP1 in the first subpixel SPX1, the second light conversion layer QDL2 may be disposed on the first capping layer CAP1 in the second subpixel SPX2, and the light transmission layer TPL may be disposed on the first capping layer CAP1 in the third subpixel SPX3. The light blocking layer BM may overlap the second organic layer 211 and the third organic layer 212 in the third direction DR3 and may not overlap the light emitting elements LE.

The first light conversion layer QDL1 may convert a portion of third light (light in the blue wavelength band) incident from a light emitting element LE into first light (light in the red wavelength band). The first light conversion layer QDL1 may include a first base resin BRS1 and first wavelength conversion particles WCP1. The first base resin BRS1 may include a light-transmitting organic material. The first wavelength conversion particles WCP1 may convert a portion of the third light (light in the blue wavelength band) incident from the light emitting element LE into the first light (light in the red wavelength band).

The second light conversion layer QDL2 may convert a portion of third light (light in the blue wavelength band) incident from a light emitting element LE into second light (light in the green wavelength band). The second light conversion layer QDL2 may include a second base resin BRS2 and second wavelength conversion particles WCP2. The second base resin BRS2 may include a light-transmitting organic material. The second wavelength conversion particles WCP2 may convert a portion of the third light (light in the blue wavelength band) incident from the light emitting element LE into the second light (light in the green wavelength band).

The light transmission layer TPL may include a light-transmitting organic material.

For example, the first base resin BRS1, the second base resin BRS2, and the light transmission layer TPL may include epoxy resin, acrylic resin, cardo resin, and/or imide resin. The first and second wavelength conversion particles WCP1 and WCP2 may be quantum dots, quantum rods, fluorescent materials, and/or phosphorescent materials.

The light blocking layer BM may include a first light blocking layer BM1 and a second light blocking layer BM2 stacked sequentially. A length of the first light blocking layer BM1 in the first direction DR1 or a length of the first light blocking layer BM1 in the second direction DR2 may be greater than a length of the second light blocking layer BM2 in the first direction DR1 or a length of the second light blocking layer BM2 in the second direction DR2. The first light blocking layer BM1 and the second light blocking layer BM2 may be made of an organic layer such as acryl resin, epoxy resin, phenolic resin, polyamide resin, and/or polyimide resin. The first light blocking layer BM1 and the second light blocking layer BM2 may include a light blocking material to prevent light of a light emitting element LE of one subpixel from travelling to a neighboring subpixel. For example, the first light blocking layer BM1 and the second light blocking layer BM2 may include an inorganic black pigment such as carbon black and/or an organic black pigment.

A second capping layer CAP2 may be disposed on the first capping layer CAP1 and the light blocking layer BM. The second capping layer CAP2 may be disposed on side and upper surfaces of the light blocking layer BM. For example, the second capping layer CAP2 may be disposed on side surfaces of the first light blocking layer BM1 and side and upper surfaces of the second light blocking layer BM2.

A reflective layer RF may be disposed between the light blocking layer BM and the first light conversion layer QDL1, between the light blocking layer BM and the second light conversion layer QDL2, and between the light blocking layer BM and the light transmission layer TPL. The reflective layer RF may be disposed on the second capping layer CAP2 disposed on the side surfaces of the first light blocking layer BM1 and the side surfaces of the second light blocking layer BM2. The reflective layer RF may reflect light travelling in the lateral direction from the first light conversion layer QDL1, the second light conversion layer QDL2, and the light transmission layer TPL.

The reflective layer RF may include a metal material with high reflectivity, such as aluminum (Al). A thickness of the reflective layer RF may be about 0.1 μm.

Alternatively, to serve as distributed Bragg reflectors, the reflective layer RF may include M (M is an integer of 2 or more) pairs of first and second layers having different refractive indices. In this case, M first layers and M second layers may be arranged alternately. The first and second layers may be made of an inorganic layer, for example, silicon nitride (SiNₓ), silicon oxynitride (SiON), silicon oxide (SiOₓ), titanium oxide (TiOₓ), or aluminum oxide (AlOₓ).

A third capping layer CAP3 may be disposed on the second capping layer CAP2, the first light conversion layer QDL1, the second light conversion layer QDL2, and the light transmission layer TPL.

The first capping layer CAP1, the second capping layer CAP2, and the third capping layer CAP3 may be made of an inorganic layer, for example, silicon nitride (SiNₓ), silicon oxynitride (SiON), silicon oxide (SiOₓ), titanium oxide (TiOₓ), and/or aluminum oxide (AIOₓ). The first light conversion layer QDL1, the second light conversion layer QDL2, and the light transmission layer TPL may be encapsulated by the first capping layer CAP1, the second capping layer CAP2, and the third capping layer CAP3.

A fourth organic layer 213 may be disposed on the third capping layer CAP3. A plurality of color filters CF1 through CF3 may be disposed on the fourth organic layer 213. The color filters CF1 through CF3 may include first color filters CF1, second color filters CF2, and third color filters CF3.

A first color filter CF1 disposed in the first subpixel SPX1 may transmit first light (light in the red wavelength band) and absorb or block third light (light in the blue wavelength band). Therefore, the first color filter CF1 may transmit the first light (light in the red wavelength band) into which a portion of the third light (light in the blue wavelength band) emitted from a light emitting element LE has been converted by the first light conversion layer QDL1 and may absorb or block the third light (light in the blue wavelength band), which has not been converted by the first light conversion layer QDL1. Accordingly, the first subpixel SPX1 may output the first light (light in the red wavelength band).

A second color filter CF2 disposed in the second subpixel SPX2 may transmit second light (light in the green wavelength band) and absorb or block third light (light in the blue wavelength band). Therefore, the second color filter CF2 may transmit the second light (light in the green wavelength band) into which a portion of the third light (light in the blue wavelength band) emitted from a light emitting element LE has been converted by the second light conversion layer QDL2 and may absorb or block the third light (light in the blue wavelength band), which has not been converted by the second light conversion layer QDL2. Accordingly, the second subpixel SPX2 may output the second light (light in the green wavelength band).

A third color filter CF3 disposed in the third subpixel SPX3 may transmit third light (light in the blue wavelength band). Therefore, the third color filter CF3 may transmit the third light (light in the blue wavelength band) that passes through the light transmission layer TPL after being emitted from a light emitting element LE. Accordingly, the third subpixel SPX3 may emit the third light (light in the blue wavelength band).

The first color filter CF1, the second color filter CF2, and the third color filter CF3 overlapping each other in the third direction DR3 may overlap the light blocking layer BM in the third direction DR3.

A fifth organic layer 214 for planarization may be disposed on the color filters CF1 through CF3

The fourth organic layer 213 and the fifth organic layer 214 may be made of acryl resin, epoxy resin, phenolic resin, polyamide resin, and/or polyimide resin.

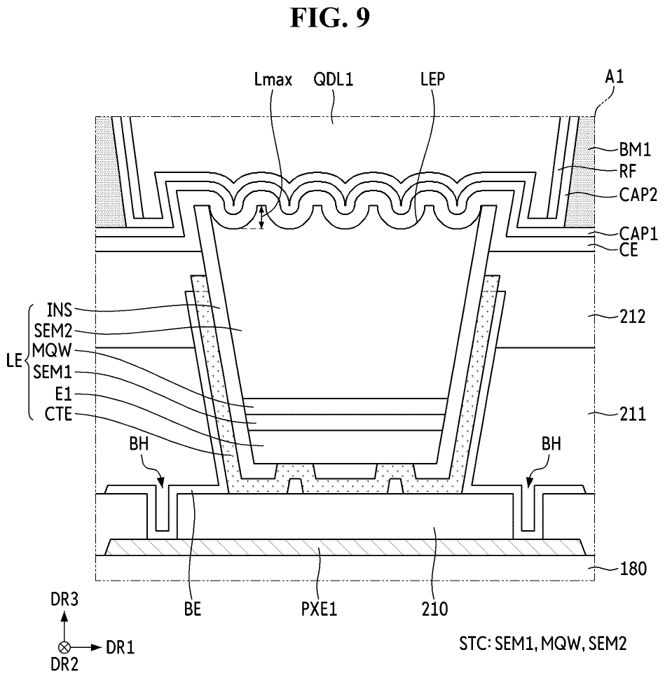

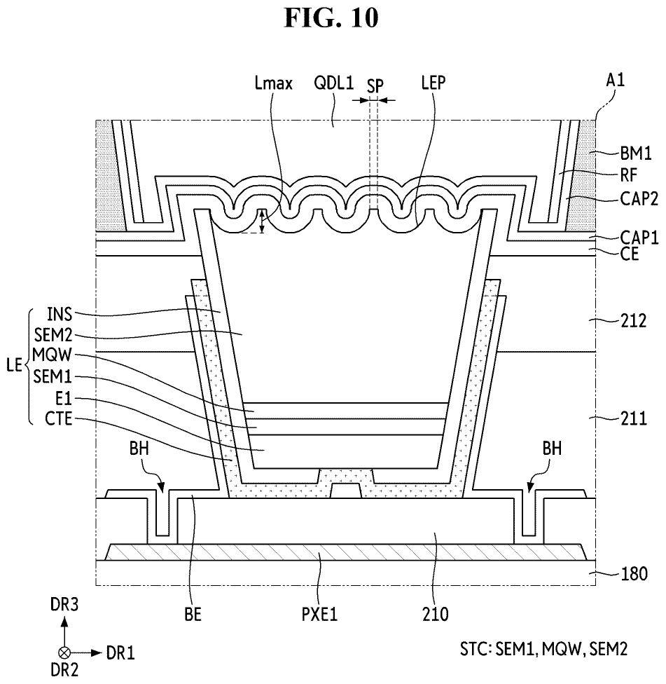

FIG. 9 is a detailed cross-sectional view of an embodiment of the area A1 of FIG. 7. FIG. 10 is a detailed cross-sectional view of an embodiment of the area A1 of FIG. 7.

FIGS. 9 and 10 show embodiments different from the embodiment of FIG. 8 in relation to the contact electrode CTE of the light emitting element LE. In addition, FIGS. 9 and 10 show different embodiments in relation to the connection structure of the contact electrode CTE and the conductive layer E1 of the light emitting element LE. In the description of the following embodiments, descriptions overlapping those of at least one embodiment described above will be omitted, and differences between the embodiments will be mainly described.

Referring to FIGS. 9 and 10, a light emitting element LE may include a single contact electrode CTE rather than a plurality of contact electrodes CTE (e.g., as shown in FIG. 8).

In one or more embodiments, the contact electrode CTE may be connected to a conductive layer E1 in one area or a plurality of areas of the conductive layer E1. For example, as illustrated in FIG. 9, a plurality of areas of the conductive layer E1 may be exposed without being covered by a protective layer INS. The contact electrode CTE may be connected to the conductive layer E1 in each of the areas of the conductive layer E1. Accordingly, even if the contact electrode CTE is not connected to the conductive layer E1 in any one of the areas due to a process error, it may be connected to the conductive layer E1 in the other areas, thereby preventing the light emitting element LE from not lighting up.

In one or more embodiments, the protective layer INS may include a single opening area on a lower surface of the conductive layer E1 as illustrated in FIG. 10. A portion of the conductive layer E1 that is exposed by the opening area of the protective layer INS may be connected to the contact electrode CTE.

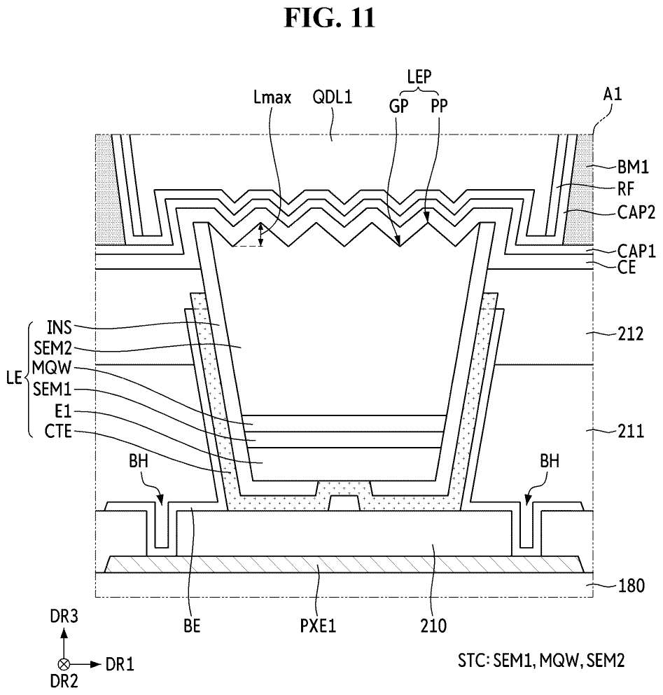

FIG. 11 is a detailed cross-sectional view of an embodiment of the area A1 of FIG. 7. FIG. 11 shows an embodiment different from the embodiment of FIG. 10 in relation to light extraction patterns LEP of a light emitting element LE.

Although FIG. 11 discloses a modification of the embodiment of FIG. 10, the light extraction patterns LEP according to the embodiment of FIG. 11 may also be applied to the light emitting element LE according to the embodiment of FIG. 8 or FIG. 9. For example, each embodiment disclosed in the present disclosure may be applied or implemented alone or may be applied or implemented together with at least one other embodiment, and all possible combinations of the embodiments may fall within the scope of the present disclosure.

Referring to FIG. 11, the light extraction patterns LEP may include groove portions GP having a substantially “V”-shaped cross-sectional shape and protrusion portions PP disposed around the groove portions GP. For example, the groove portions GP of the light extraction patterns LEP may have a cone shape with an apex facing downward.

In one or more embodiments, the light extraction patterns LEP may be repeatedly arranged on a light output surface of a light emitting element LE at intervals SP as illustrated in FIG. 10 or may be repeatedly arranged on the light output surface of the light emitting element LE in contact with each other as illustrated in FIG. 11.

In one or more embodiments, outermost light extraction patterns LEP from among the light extraction patterns LEP disposed on the light output surface of the light emitting element LE may contact ends of the light output surface (e.g., parts where an upper surface and side surfaces of the light emitting element LE meet). In addition, the groove portions GP of the light extraction patterns LEP may not directly contact the ends of the light output surface. For example, the outermost light extraction patterns LEP may meet side ends of the light emitting element LE at the protrusion portions PP.

In the description of embodiments, the protrusion portion PP of each of the light extraction patterns LEP may include a peak located at a highest height (e.g., a highest point) in each of the light extraction patterns LEP, and the groove portion GP of each of the light extraction patterns LEP may include a valley located at a lowest height (e.g., a lowest point) in each of the light extraction patterns LEP. More broadly, the protrusion portion PP of each of the light extraction patterns LEP may mean an upper portion of each of the light extraction patterns LEP, and the groove portion GP of each of the light extraction patterns LEP may mean a lower portion of each of the light extraction patterns LEP. For example, the protrusion portion PP of each of the light extraction patterns LEP may include a portion located above half of the highest height (e.g., the highest point) of each of the light extraction patterns LEP, and the groove portion GP of each of the light extraction patterns LEP may include a portion located below half of the highest height (e.g., the highest point) of each of the light extraction patterns LEP.

Because the outermost light extraction patterns LEP contact side surfaces of the light emitting element LE at parts where the protrusion portions PP are formed, the stability of the light emitting element LE can be secured. For example, a protective layer INS may not contact the groove portions GP of the light extraction patterns LEP. Accordingly, the protective layer INS can stably cover side surfaces of a semiconductor stack STC up to a height corresponding to a height of the protrusion portions PP of the light extraction patterns LEP. Accordingly, an appropriate distance can be secured between electrodes (e.g., a contact electrode CTE and/or connection electrodes BE) disposed on the outside of the protective layer INS and the semiconductor stack STC, and a short-circuit defect of the light emitting element LE can be prevented. In addition, because the side surfaces of the semiconductor stack STC are stably covered by the protective layer INS, even when the light emitting element LE manufactured on a semiconductor substrate is placed on a transfer substrate or a display substrate using a laser in a process for placing the light emitting element LE on each pixel electrode PXE1/PXE2/PXE3, damage to the light emitting element LE at an interface between the semiconductor stack STC and the protective layer INS can be prevented or minimized.

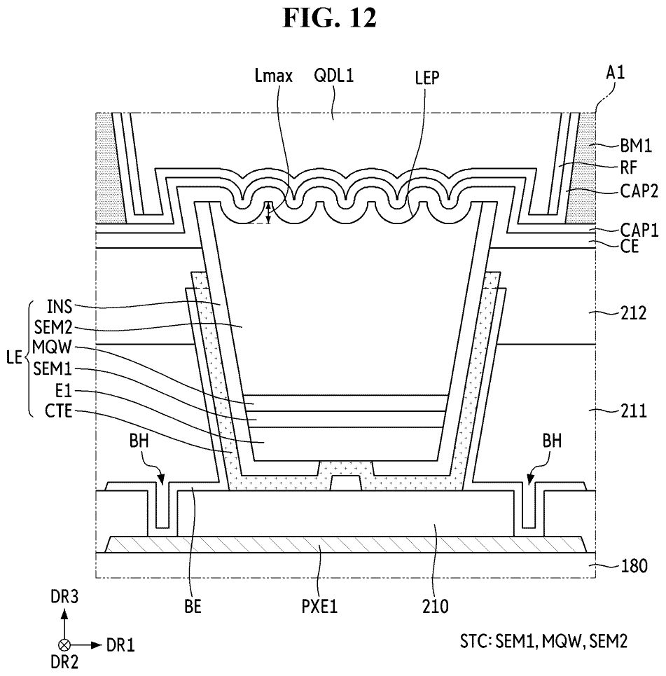

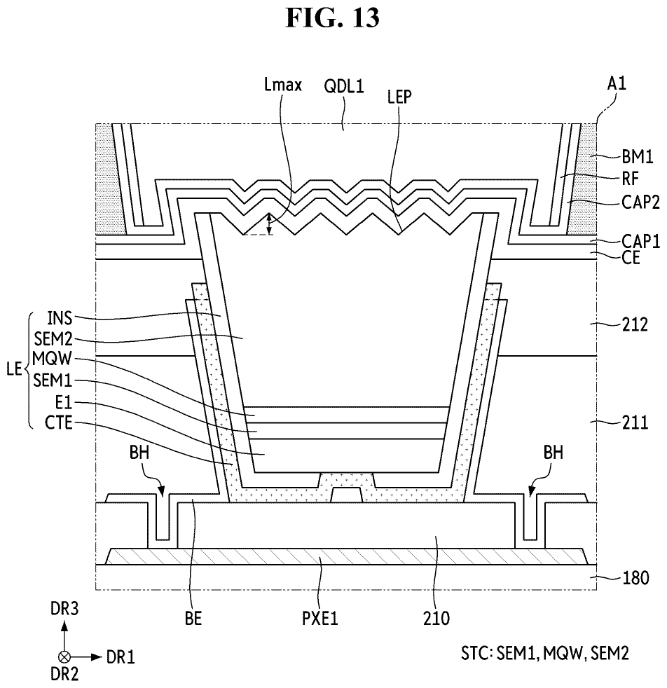

FIG. 12 is a detailed cross-sectional view of an embodiment of the area A1 of FIG. 7. FIG. 13 is a detailed cross-sectional view of an embodiment of the area A1 of FIG. 7. FIGS. 12 and 13 show embodiments respectively different from the embodiments of FIGS. 10 and 11 in relation to light extraction patterns LEP.

Referring to FIGS. 12 and 13, in a plan view, the light extraction patterns LEP may be located inside a light output surface of the light emitting element LE and may be spaced (e.g., spaced apart) from side surfaces of the semiconductor stack STC. For example, outermost light extraction patterns LEP from among the light extraction patterns LEP disposed on the light output surface of the light emitting element LE may be spaced (e.g., spaced apart) from ends of the light output surface (e.g., parts where an upper surface and side surfaces of the semiconductor stack STC meet) by a certain distance. Because the light extraction patterns LEP are disposed inside the light output surface of the light emitting element LE, the physical and/or electrical stability of the light emitting element LE can be further increased.

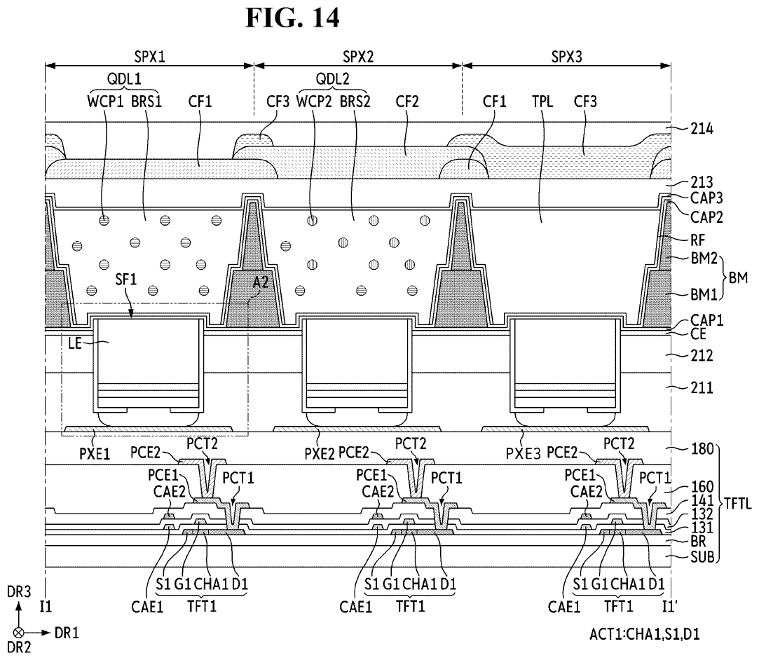

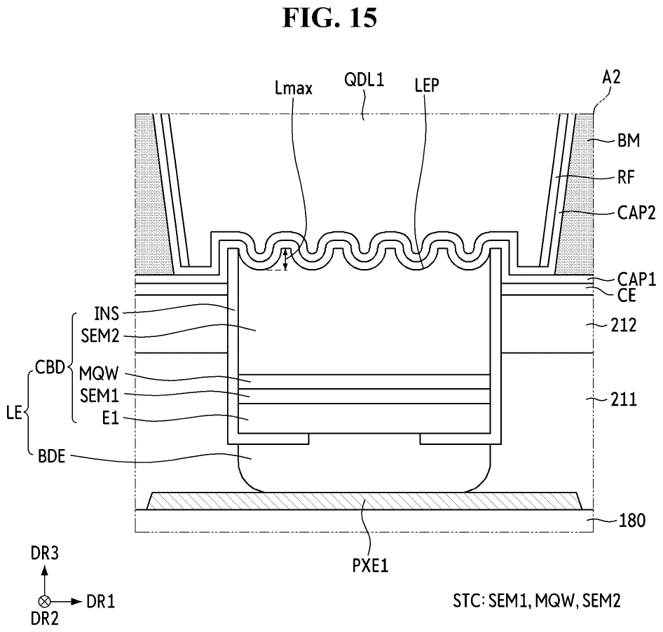

FIG. 14 is a cross-sectional view illustrating an example of a cross section of the display panel corresponding to the line 11-11′ of FIG. 6. FIG. 15 is a detailed cross-sectional view of an embodiment of an area A2 of FIG. 14.

FIGS. 14 and 15 show an embodiment different from the embodiment of FIGS. 7 and 8 in relation to a light emitting element layer including light emitting elements LE. For example, FIGS. 14 and 15 illustrate an embodiment of a display panel 100 in which the light emitting elements LE are directly disposed on pixel electrodes PXE1 through PXE3.

Referring to FIGS. 14 and 15, each of the light emitting elements LE may include a body portion CBD and a bonding electrode BDE (also referred to as an “electrode” or a “bonding layer”) disposed on a lower surface of the body portion CBD. The light emitting elements LE may be placed on the pixel electrodes PXE1 through PXE3 (or bonding pads connected to the pixel electrodes PXE1 through PXE3) by the bonding electrodes BDE, respectively. For example, the light emitting elements LE can be stably placed or bonded on the pixel electrodes PXE1 through PXE3 using a bonding method such as eutectic bonding.

When the light emitting elements LE are directly placed or bonded on the pixel electrodes PXE1 through PXE3, the display panel 100 may not include the first organic layer 210 and the connection electrodes BE of FIG. 7. In one or more embodiments, each of the pixel electrodes PXE1 through PXE3 may be composed of multiple layers including a metal layer for proper connection with a light emitting element LE, but the present disclosure is not limited thereto.

The body portion CBD may be an LED chip body including a semiconductor stack STC. For example, the body portion CBD may include a first semiconductor layer SEM1, an active layer MQW, and a second semiconductor layer SEM2 sequentially disposed or stacked along a direction (e.g., the third direction DR3). In one or more embodiments, the body portion CBD may further include a conductive layer E1 disposed on a surface (e.g., a lower surface) of the first semiconductor layer SEM1 and a protective layer INS covering at least side surfaces of the semiconductor stack STC.

In one or more embodiments, the conductive layer E1 may have a shape and/or size corresponding to those of the first semiconductor layer SEM1, the active layer MQW, and the second semiconductor layer SEM2. For example, the conductive layer E1 may be etched and patterned together with the first semiconductor layer SEM1, the active layer MQW, and the second semiconductor layer SEM2 on a manufacturing substrate for manufacturing the light emitting elements LE (e.g., a semiconductor substrate for growing semiconductor layers). Accordingly, the conductive layer E1 may have a planar shape and size corresponding to the planar shape and size (e.g., area) of the first semiconductor layer SEM1, the active layer MQW, and the second semiconductor layer SEM2. However, the shape or size of the conductive layer E1 may vary according to embodiments.

In one or more embodiments, the protective layer INS may further cover the conductive layer E1. For example, the protective layer INS may cover side surfaces of the conductive layer E1, the first semiconductor layer SEM1, the active layer MQW, and the second semiconductor layer SEM2.

In one or more embodiments, the protective layer INS may partially cover a lower surface of the conductive layer E1. For example, the protective layer INS may cover an edge portion of the lower surface of the conductive layer E1 and may include an opening exposing a central portion of the conductive layer E1. However, the present disclosure is not limited thereto. For example, the protective layer INS may cover only the side surfaces of the conductive layer E1 or may not cover the conductive layer E1.

In one or more embodiments, the body portion CBD may have a quadrangular cross-sectional shape such as a square, rectangular, and/or trapezoidal shape. For example, the body portion CBD may be a vertical micro-LED chip having a square or rectangular cross-sectional shape. Alternatively, the body portion CBD may have a trapezoidal cross-sectional shape. The type, shape, and/or size of the body portion CBD may vary according to embodiments.

The bonding electrode BDE may include a conductive material (e.g., a bonding metal) suitable for bonding. In one or more embodiments, the bonding electrode BDE may be disposed on a lower surface of the protective layer INS and may be electrically connected to the conductive layer E1 exposed by the opening of the protective layer INS. The bonding electrode BDE may be bonded onto each pixel electrode (e.g., a first pixel electrode PXE1, a second pixel electrode PXE2, or a third pixel electrode PXE3) and electrically connected to the pixel electrode. In one or more embodiments, the bonding electrode BDE may be composed of multiple layers including a bonding metal layer and a capping layer disposed on at least one surface of the bonding metal layer. In one or more embodiments, the bonding electrode BDE may further include a reflective layer disposed between the bonding metal layer and the body portion CBD. The reflective layer may be formed of a metal layer including a metal having high light reflectivity or may be formed of distributed Bragg reflectors.

In one or more embodiments, each of the light emitting elements LE may further include a side reflective layer disposed on side surfaces of the protective layer INS. In one or more embodiments, the side reflective layer may be formed of a metal layer including a metal having high light reflectivity or may be formed of distributed Bragg reflectors.

Each of the light emitting elements LE may include light extraction patterns LEP formed on a light output surface thereof. For example, each of the light emitting elements LE may include the light extraction patterns LEP formed on an upper surface of the semiconductor stack STC.

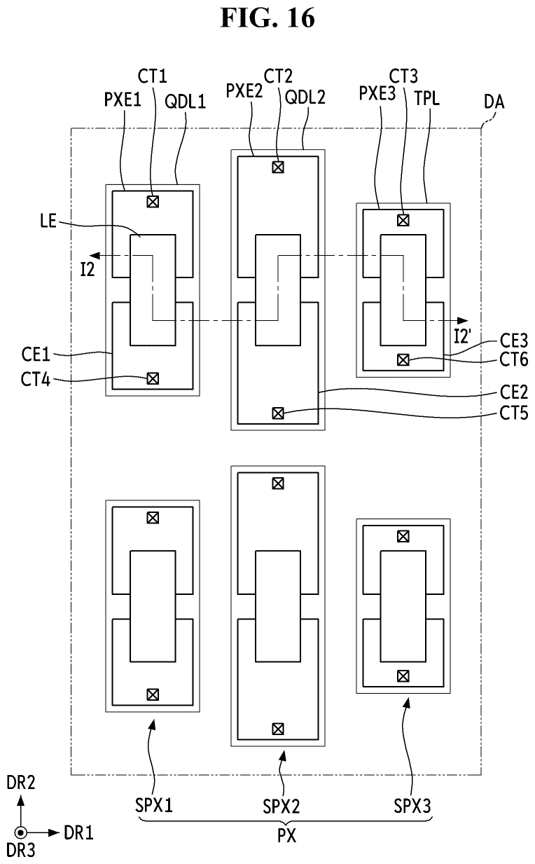

FIG. 16 is a layout view illustrating pixels PX of a display area DA according to one or more embodiments. The embodiment of FIG. 16 is different from the embodiment of FIG. 6 in that a light emitting element LE is disposed on a pixel electrode PXE1/PXE2/PXE3 and a common electrode CE1/CE2/CE3 in each of a first subpixel SPX1, a second subpixel SPX2, and a third subpixel SPX3.

Referring to FIG. 16, the pixel electrode PXE1/PXE2/PXE3 and the common electrode CE1/CE2/CE3 may be arranged along the second direction DR2 in each of the first subpixel SPX1, the second subpixel SPX2, and the third subpixel SPX3. Each of the pixel electrodes PXE1 through PXE3 and the common electrodes CE1 through CE3 may have a rectangular planar shape, but the present disclosure is not limited thereto. The area of a first pixel electrode PXE1 may be equal to the area of a first common electrode CE1, the area of a second pixel electrode PXE2 may be equal to the area of a second common electrode CE2, and the area of a third pixel electrode PXE3 may be equal to the area of a third common electrode CE3, but the present disclosure is not limited thereto.

When the light conversion efficiency of a second light conversion layer QDL2 is lower than the light conversion efficiency of a first light conversion layer QDL1, the area of the second pixel electrode PXE2 may be larger than the area of the first pixel electrode PXE1, and the area of the second common electrode CE2 may be larger than the area of the first common electrode CE1. In addition, because the first light conversion layer QDL1 must convert light whereas a light transmission layer TPL transmits light of a light emitting element LE as it is, the area of the first pixel electrode PXE1 may be larger than the area of the third pixel electrode PXE3, and the area of the first common electrode CE1 may be larger than the area of the third common electrode CE3.

The first common electrode CE1 may be connected to a second power line VSL, to which a second driving voltage VSS is applied, through a first common connection hole CT4. The second common electrode CE2 may be connected to the second power line VSL through a second common connection hole CT5. The third common electrode CE3 may be connected to the second power line VSL through a third common connection hole CT6. Therefore, the second driving voltage VSS may be applied to each of the common electrodes CE1 through CE3.

In each of the first subpixel SPX1, the second subpixel SPX2, and the third subpixel SPX3, a light emitting element LE may be disposed on a pixel electrode PXE1/PXE2/PXE3 and a common electrode CE1/CE2/CE3. For example, a portion of the light emitting element LE may be disposed on the pixel electrode PXE1/PXE2/PXE3, and another portion of the light emitting element LE may be disposed on the common electrode CE1/CE2/CE3. A length of the light emitting element LE in the second direction DR2 may be greater than a length of the light emitting element LE in the first direction DR1.

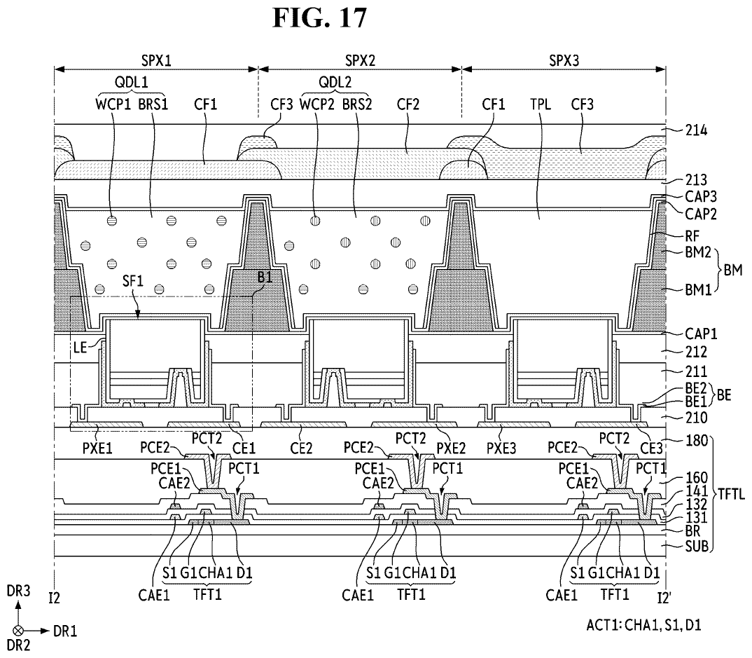

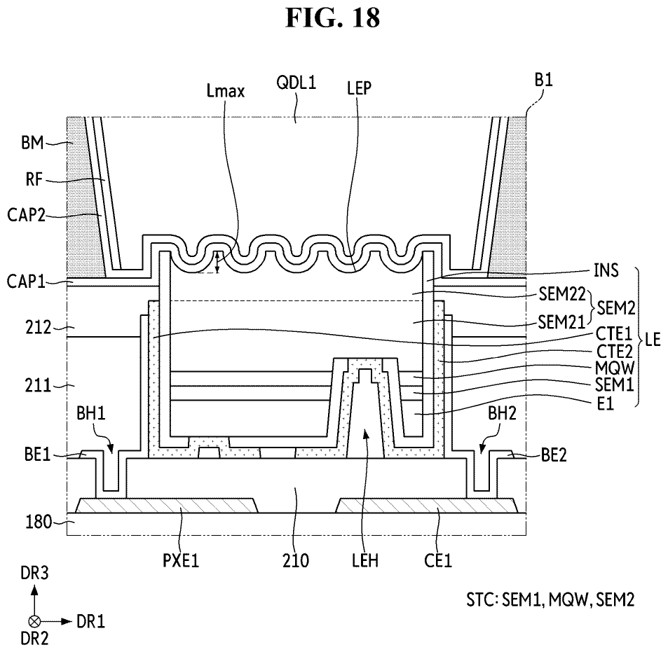

FIG. 17 is a cross-sectional view illustrating an example of a cross section of a display panel corresponding to the line 12-12′ of FIG. 16. FIG. 18 is a detailed cross-sectional view of an embodiment of an area B1 of FIG. 17. The embodiment of FIGS. 17 and 18 is different from the embodiment of FIGS. 7 and 8 in that each light emitting element LE is a flip-type micro-LED.

Referring to FIGS. 17 and 18, a pixel electrode layer including pixel electrodes PXE1 through PXE3 and common electrodes CE1 through CE3 may be disposed on a second planarization layer 180.

Each light emitting element LE may be a flip-type micro-LED. The flip-type micro-LED refers to an LED in which contact electrodes CTE1 and CTE2 are formed on a surface (e.g., a lower surface) of a light emitting element LE.

In one or more embodiments, a second semiconductor layer SEM2 may include a heavily doped layer SEM21 and a lightly doped layer SEM22 having different doping concentrations. The heavily doped layer SEM21 may be a portion of the second semiconductor layer SEM2 in which an n-type dopant is equal to or higher than a suitable threshold (e.g., a predetermined threshold) value and may be adjacent to an active layer MQW. The lightly doped layer SEM22 may be another portion of the second semiconductor layer SEM2 in which the n-type dopant is lower than the suitable threshold (e.g., the predetermined threshold) value and may include a light output surface or may be adjacent to the light output surface. For example, the lightly doped layer SEM22 may include indium aluminum gallium nitride (InAlGaN), gallium nitride (GaN), aluminum gallium nitride (AlGaN), indium gallium nitride (InGaN), aluminum nitride (AlN), and/or indium nitride (InN), whose n-type dopant is lower than the suitable threshold (e.g., a predetermined threshold) value. Although the lightly doped layer SEM22 is described as a portion of the second semiconductor layer SEM2 in FIG. 18, the present disclosure is not limited thereto. For example, the heavily doped layer SEM21 may be referred to as the second semiconductor layer SEM2, and the lightly doped layer SEM22 may be referred to as an un-doped semiconductor layer. The lightly doped layer SEM22 may be disposed on the heavily doped layer SEM21. In this case, light extraction patterns LEP may be formed on an upper surface of the lightly doped layer SEM22.

However, the present disclosure is not limited thereto. For example, in the entire second semiconductor layer SEM2, the n-type dopant may be equal to or higher than the suitable threshold (e.g., a predetermined threshold) value. In this case, the entire second semiconductor layer SEM2 may be a heavily doped layer, and the light extraction patterns LEP may be formed on an upper surface of the heavily doped layer.

A hole LEH may be formed to pass through a conductive layer E1, a first semiconductor layer SEM1, and the active layer MQW of each light emitting element LE and expose the second semiconductor layer SEM2. The hole LEH may have a circular planar shape, but the present disclosure is not limited thereto. For example, the hole LEH may also have an elliptical planar shape or a polygonal planar shape such as a quadrangle.

In addition, a protective layer INS may be disposed on sidewalls of the conductive layer E1, sidewalls of the first semiconductor layer SEM1, and sidewalls of the active layer MQW exposed in the hole LEH. The protective layer INS may not cover the second semiconductor layer SEM2 in the hole LEH. Therefore, the second semiconductor layer SEM2 may be exposed without being covered by the protective layer INS in the hole LEH.

A first contact electrode CTE1 may be disposed on at least one side surface of a semiconductor stack STC and at least one side surface and a lower surface of the conductive layer E1. The first contact electrode CTE1 may be disposed on the lower surface of the conductive layer E1 which is exposed without being covered by the protective layer INS. Therefore, the first contact electrode CTE1 may be electrically connected to the conductive layer E1.

A second contact electrode CTE2 may be disposed on at least one side surface of the semiconductor stack STC and at least one side surface and the lower surface of the conductive layer E1. Here, while the first contact electrode CTE1 is disposed on a first side surface of the semiconductor stack STC and a first side surface of the conductive layer E1, the second contact electrode CTE2 may be disposed on a second side surface of the semiconductor stack STC and a second side surface of the conductive layer E1.

The second contact electrode CTE2 may be disposed on the protective layer INS disposed in the hole LEH and the second semiconductor layer SEM2 exposed in the hole LEH without being covered by the protective layer INS. Therefore, the second contact electrode CTE2 may be electrically connected to the second semiconductor layer SEM2 in the hole LEH.

FIGS. 17 and 18 disclose an embodiment in which the first contact electrode CTE1 and the second contact electrode CTE2 of each light emitting element LE are disposed on a first organic layer 210. However, the present disclosure is not limited thereto. For example, the first organic layer 210 may also be disposed on a lower surface and a portion of a side surface of the first contact electrode CTE1 and a lower surface and a portion of a side surface of the second contact electrode CTE2 of each light emitting element LE. Alternatively, the first organic layer 210 may be disposed on the side surfaces of the conductive layer E1 of each light emitting element LE. Alternatively, the first organic layer 210 may be disposed on side surfaces of the first semiconductor layer SEM1, side surfaces of the active layer MQW, and side surfaces of the second semiconductor layer SEM2 of each light emitting element LE. In this case, the first organic layer 210 may be disposed on a portion of each side surface of the second semiconductor layer SEM2.

In each side surface of the semiconductor stack STC, an area adjacent to an upper surface of the semiconductor stack STC may be covered by the protective layer INS, but may be exposed without being covered by the first contact electrode CTE1 or the second contact electrode CTE2. For example, a distance (or height difference) between the upper surface of the semiconductor stack STC and the first contact electrode CTE1 in the third direction DR3 may be about 100 nm or greater. In one or more embodiments, the distance (or height difference) between the upper surface of the semiconductor stack STC and the first contact electrode CTE1 in the third direction DR3 may be greater than a maximum length Lmax of each light extraction pattern LEP in the third direction DR3. When the first contact electrode CTE1 is spaced (e.g., spaced apart) from the upper surface of the semiconductor stack STC as described above, it can be prevented from being peeled off by a chemical solution and/or the like during a manufacturing process. In addition, a distance (or height difference) between the upper surface of the semiconductor stack STC and the second contact electrode CTE2 in the third direction DR3 may be about 100 nm or greater. In addition, the distance (or height difference) between the upper surface of the semiconductor stack STC and the second contact electrode CTE2 in the third direction DR3 may be greater than the maximum length Lmax of each light extraction pattern LEP in the third direction DR3. When the second contact electrode CTE2 is spaced (e.g., spaced apart) from the upper surface of the semiconductor stack STC as described above, it can be prevented from being peeled off by a chemical solution and/or the like during a manufacturing process.

In one or more embodiments, each of the first contact electrode CTE1 and the second contact electrode CTE2 may be disposed on three side surfaces of the semiconductor stack STC. For example, when the semiconductor stack STC includes first through fourth side surfaces, in one or more embodiments, the first contact electrode CTE1 may be disposed on the first side surface, the second side surface and the third side surface, and the second contact electrode CTE2 may be disposed on the second side surface, the third side surface and the fourth side surface.

A first connection electrode BE1 connects the first contact electrode CTE1 of each light emitting element LE to a pixel electrode PXE1/PXE2/PXE3. The first connection electrode BE1 may be connected to the pixel electrode PXE1/PXE2/PXE3 exposed through a first connection hole BH1 penetrating the first organic layer 210. In addition, the first connection electrode BE1 may be disposed on an upper surface of the first organic layer 210 and the first contact electrode CTE1.

A second connection electrode BE2 connects the second contact electrode CTE2 of each light emitting element LE to a common electrode CE1/CE2/CE3. The second connection electrode BE2 may be connected to the common electrode CE1/CE2/CE3 exposed through a second connection hole BH2 penetrating the first organic layer 210. In addition, the second connection electrode BE2 may be disposed on the upper surface of the first organic layer 210 and the second contact electrode CTE2.

The first connection electrode BE1 and the second connection electrode BE2 may include molybdenum (Mo), aluminum (Al), chromium (Cr), gold (Au), titanium (Ti), nickel (Ni), neodymium (Nd), and/or copper (Cu). Alternatively, the first connection electrode BE1 and the second connection electrode BE2 may be made of a transparent conductive material (TCO) such as indium tin oxide (ITO) and/or indium zinc oxide (IZO).

The conductive layer E1 of each light emitting element LE may be connected to a pixel electrode PXE1/PXE2/PXE3 through the first contact electrode CTE1 and the first connection electrode BE1. In addition, the second semiconductor layer SEM2 of each light emitting element LE may be connected to a common electrode CE1/CE2/CE3 through the second contact electrode CTE2 and the second connection electrode BE2.

In addition, in each side surface of the semiconductor stack STC, an area adjacent to the upper surface of the semiconductor stack STC may be exposed without being covered by the first connection electrode BE1 or the second connection electrode BE2. For example, a distance (or height difference) between the upper surface of the semiconductor stack STC and the first connection electrode BE1 in the third direction DR3 and a distance (or height difference) between the upper surface of the semiconductor stack STC and the second connection electrode BE2 in the third direction DR3 may each be greater than about 100 nm. When the first connection electrode BE1 and the second connection electrode BE2 are spaced (e.g., spaced apart) from the upper surface of the semiconductor stack STC as described above, they can be prevented from being peeled off by a chemical solution and/or the like during a manufacturing process.

FIG. 18 discloses an embodiment in which the first connection electrode BE1 and the second connection electrode BE2 are formed at a lower height than the first contact electrode CTE1 and the second contact electrode CTE2 to expose upper surfaces of the first contact electrode CTE1 and the second contact electrode CTE2. However, the present disclosure is not limited thereto. For example, the first connection electrode BE1 and the second connection electrode BE2 may be formed at a lower height than the first contact electrode CTE1 and the second contact electrode CTE2 or may be formed at the same height as or above the first contact electrode CTE1 and the second contact electrode CTE2.

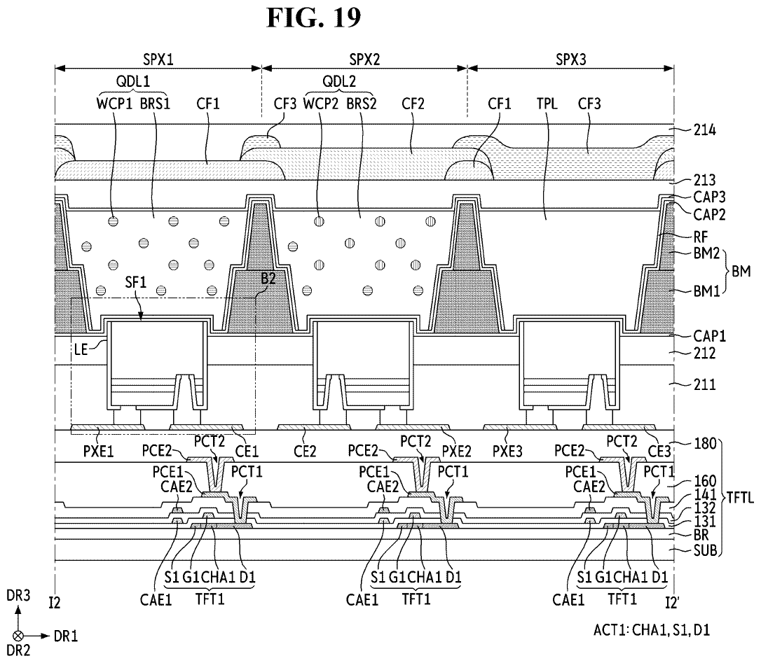

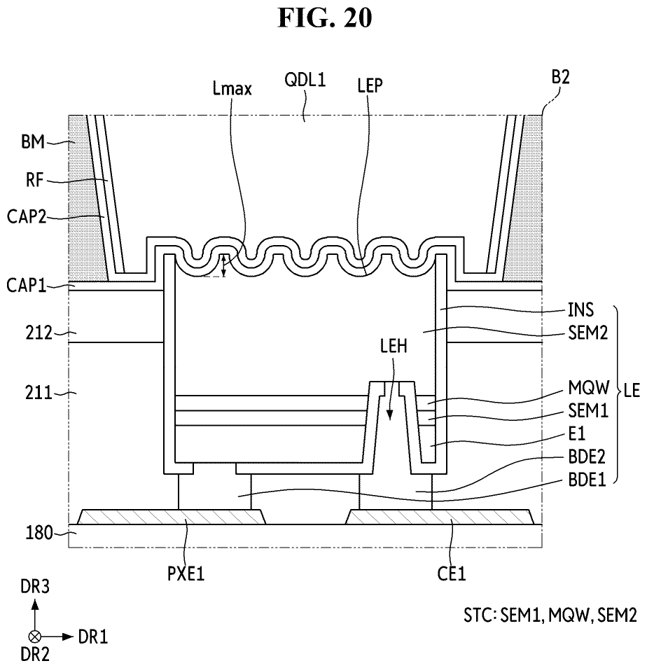

FIG. 19 is a cross-sectional view illustrating an example of a cross-section of the display panel 100 corresponding to the line 12-12′ of FIG. 16. FIG. 20 is a detailed cross-sectional view of an embodiment of the area B2 of FIG. 19. The embodiment of FIGS. 19 and 20 is different from the embodiment of FIGS. 14 and 15 in that each light emitting element LE is a flip-type micro-LED. In addition, the embodiment of FIGS. 19 and 20 is different from the embodiment of FIGS. 17 and 18 in that a light emitting element LE is directly disposed on each pixel electrode PXE1/PXE2/PXE3 and each common electrode CE.

Referring to FIGS. 19 and 20, each light emitting element LE may include a first bonding electrode BDE1 (also referred to as a “first electrode” or a “first bonding layer”) instead of the first contact electrode CTE1 and the first connection electrode BE1 of FIGS. 17 and 18. In addition, each light emitting element LE may include a second bonding electrode BDE2 (also referred to as a “second electrode” or a “second bonding layer”) instead of the second contact electrode CTE2 and the second connection electrode BE2 of FIGS. 17 and 18. In the embodiment of FIGS. 19 and 20, the display panel 100 may not include the first organic layer 210 of FIGS. 17 and 18.

The first bonding electrode BDE1 may be directly disposed or bonded on a pixel electrode PXE1/PXE2/PXE3 and electrically connected to the pixel electrode PXE1/PXE2/PXE3. The first bonding electrode BDE1 may be disposed on a lower surface of a conductive layer E1, which is exposed without being covered by a protective layer INS and may be electrically connected to the conductive layer E1. Therefore, the pixel electrode PXE1/PXE2/PXE3 and the conductive layer E1 of each light emitting element LE may be electrically connected through the first bonding electrode BDE1.

The second bonding electrode BDE2 may be directly disposed or bonded on a common electrode CE1/CE2/CE3 and electrically connected to the common electrode CE1/CE2/CE3. The second bonding electrode BDE2 may be disposed on a second semiconductor layer SEM2, which is exposed in a hole LEH without being covered by the protective layer INS and may be electrically connected to the second semiconductor layer SEM2. Therefore, the common electrode CE1/CE2/CE3 and the second semiconductor layer SEM2 of each light emitting element LE may be electrically connected through the second bonding electrode BDE2.

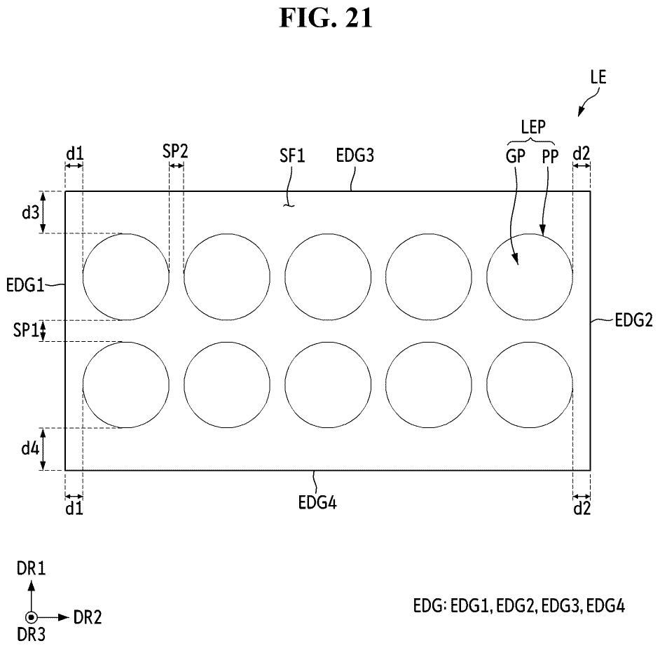

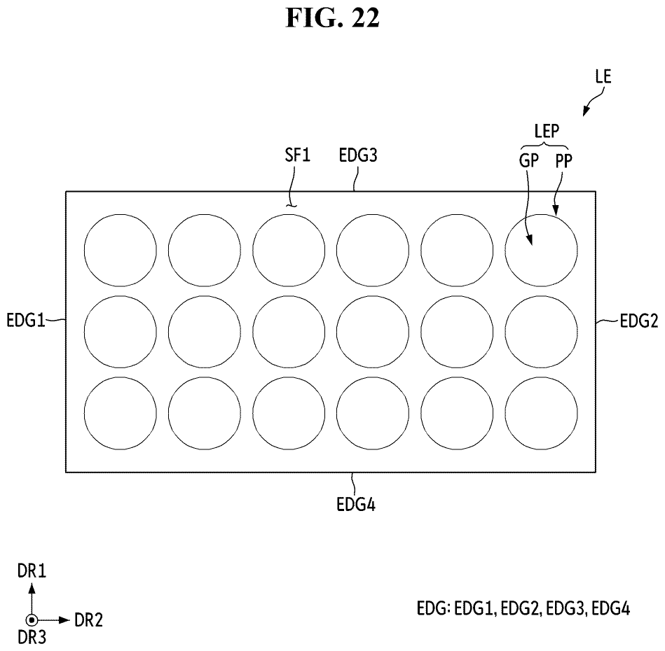

FIG. 21 is a plan view of a light emitting element LE according to one or more embodiments. FIG. 22 is a plan view of a light emitting element LE according to one or more embodiments. For example, FIGS. 21 and 22 show different embodiments in relation to light extraction patterns LEP that can be disposed on a light output surface SF1 of a light emitting element LE.

FIGS. 21 and 22 illustrate rough planar shapes of light emitting elements LE based on light output surfaces SF1 of the light emitting elements LE. The light output surface SF1 of each of the light emitting elements LE illustrated in FIGS. 21 and 22 may be an upper surface of a semiconductor stack STC. Although FIGS. 21 and 22 disclose embodiments in which the light output surface SF1 of a light emitting element LE has a rectangular planar shape, the planar shape of the light emitting element LE may vary according to embodiments.

Referring to FIGS. 21 and 22, a light emitting element LE may include light extraction patterns LEP disposed or formed on the light output surface SF1. In one or more embodiments, the light extraction patterns LEP may have a substantially circular planar shape, but the present disclosure is not limited thereto. For example, the light extraction patterns LEP may also have an elliptical shape, a polygonal shape, or other shapes in a plan view.

The light extraction patterns LEP may be repeatedly disposed on the light output surface SF1 of the light emitting element LE along at least one direction. For example, the light extraction patterns LEP may be arranged in a plurality of columns along the first direction DR1 and the second direction DR2. In one or more embodiments, the light extraction patterns LEP may be arranged in a smaller number of columns in a short-side direction of the light emitting element LE, for example, along the first direction DR1 and may be arranged in a greater number of columns in a long-side direction of the light emitting element LE, for example, along the second direction DR2. For example, the light extraction patterns LEP may be arranged in two or three columns along the first direction DR1 and may be arranged in four or more columns along the second direction DR2.

The number, shape, size, arrangement interval, and/or arrangement structure of the light extraction patterns LEP may vary according to embodiments. For example, depending on a length (e.g., a short-side length) of the light output surface SF1 of the light emitting element LE in the first direction DR1 and a length (e.g., a diameter) of each light extraction pattern LEP in the first direction DR1, the light extraction patterns LEP may be arranged in one column or two or more columns along the first direction DR1. For example, as the length of each light extraction pattern LEP in the first direction DR1 relative to the short-side length of the light output surface SF1 of the light emitting element LE decreases, the light extraction patterns LEP may be arranged in a greater number of columns along the first direction DR1. Alternatively, as the length of each light extraction pattern LEP in the first direction DR1 relative to the short-side length of the light output surface SF1 of the light emitting element LE decreases, the light extraction patterns LEP may be arranged at larger intervals along the first direction DR1. Similarly, depending on a length (e.g., a long-side length) of the light output surface SF1 of the light emitting element LE in the second direction DR2 and a length (e.g., a diameter) of each light extraction pattern LEP in the second direction DR2, the light extraction patterns LEP may be arranged in one column or two or more columns along the second direction DR2.

In one or more embodiments, the light extraction patterns LEP may be spaced (e.g., spaced apart) from each other in at least one of the first direction DR1 and the second direction DR2. For example, the light extraction patterns LEP may be arranged at first intervals SP1 in the first direction DR1 and arranged at second intervals SP2 in the second direction DR2. Lengths (or distances) of the first intervals SP1 and the second intervals SP2 may be the same or different. In one or more embodiments, the light extraction patterns LEP may be arranged at regular intervals in at least one of the first direction DR1 and the second direction DR2, but the present disclosure is not limited thereto. When the light extraction patterns LEP are arranged at regular intervals, the light output characteristics of the light emitting element LE can be made more uniform.

FIGS. 21 and 22 disclose embodiments in which the light extraction patterns LEP are spaced (e.g., spaced apart) from each other. However, the present disclosure is not limited thereto. For example, the light extraction patterns LEP may also be arranged to contact each other in at least one of the first direction DR1 and the second direction DR2.

In one or more embodiments, the light extraction patterns LEP may be spaced (e.g., spaced apart) from ends EDG of the light output surface SF1 of the light emitting element LE and thus may be arranged inside the ends EDG. For example, the light extraction patterns LEP may not be disposed at the ends EDG of the light output surface SF1.

In one or more embodiments, the light extraction patterns LEP may be arranged at a position spaced (e.g., spaced apart) from a first end EDG1 and a second end EDG2 of the light output surface SF1 by a first distance d1 and a second distance d2, respectively. The first end EDG1 and the second end EDG2 of the light emitting element LE may extend in the first direction DR1 and may be located at both ends of the light output surface SF1 in the second direction DR2. The first distance d1 and the second distance d2 may be the same or different from each other. In addition, the light extraction patterns LEP may be arranged at a position spaced (e.g., spaced apart) from a third end EDG3 and a fourth end EDG4 of the light output surface SF1 by a third distance d3 and a fourth distance d4, respectively. The third end EDG3 and the fourth end EDG4 of the light emitting element LE may extend in the second direction DR2 and may be located at both ends of the light output surface SF1 in the first direction DR1. The third distance d3 and the fourth distance d4 may be the same or different from each other.

Because the light extraction patterns LEP are spaced (e.g., spaced apart) from the ends EDG of the light output surface SF1 of the light emitting element LE, the stability of the light emitting element LE can be secured or improved. For example, because groove portions GP of the light extraction patterns LEP, which have a relatively low height, are spaced (e.g., spaced apart) from the ends EDG of the light output surface SF1, side surfaces of the semiconductor stack STC can be stably covered by a protective layer INS. Accordingly, a short-circuit defect of the light emitting element LE can be prevented, and the electrical stability of the light emitting element LE can be increased. In addition, even if a laser is irradiated to the light emitting element LE during a process of transferring the light emitting element LE, the light emitting element LE can be prevented from being damaged at the ends of the light emitting element LE, for example, at an interface between the semiconductor stack STC and the protective layer INS. Therefore, a change in the characteristics of the light emitting element LE or a defect in the light emitting element LE due to the damage to the light emitting element LE can be prevented. Accordingly, the luminance dispersion of the light emitting element LE can be prevented or reduced, and the image quality of a display device 10 including such light emitting elements LE can be improved.

In one or more embodiments, the light extraction patterns LEP may be spaced (e.g., spaced apart) from at least one end EDG of the light emitting element LE by the same distance. For example, a light extraction pattern LEP closest to the first end EDG1 of the light output surface SF1 from among light extraction patterns LEP disposed in a first column of the light output surface SF1 in the first direction DR1 and a light extraction pattern LEP closest to the first end EDG1 of the light output surface SF1 from among light extraction patterns LEP disposed in a second column of the light output surface SF1 in the first direction DR1 may be spaced (e.g., spaced apart) from the first end EDG1 of the light output surface SF1 by the same distance (e.g., the first distance d1). Because the light extraction patterns LEP are spaced (e.g., spaced apart) from at least one end EDG of the light emitting element LE by the same distance, the light output characteristics of the light emitting element LE can be made more uniform at the end EDG of the light emitting element LE.

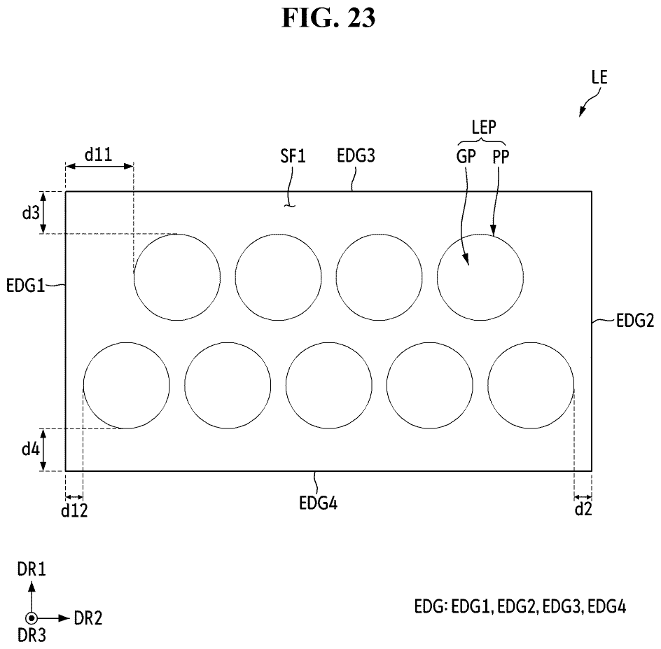

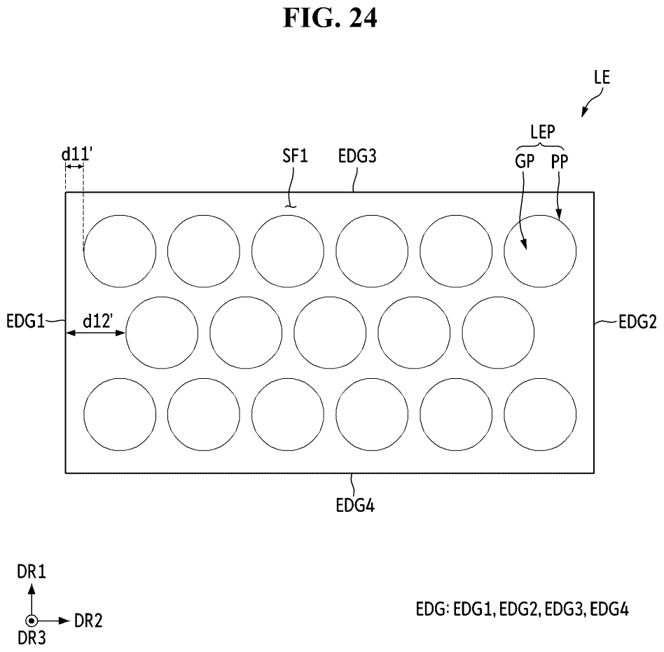

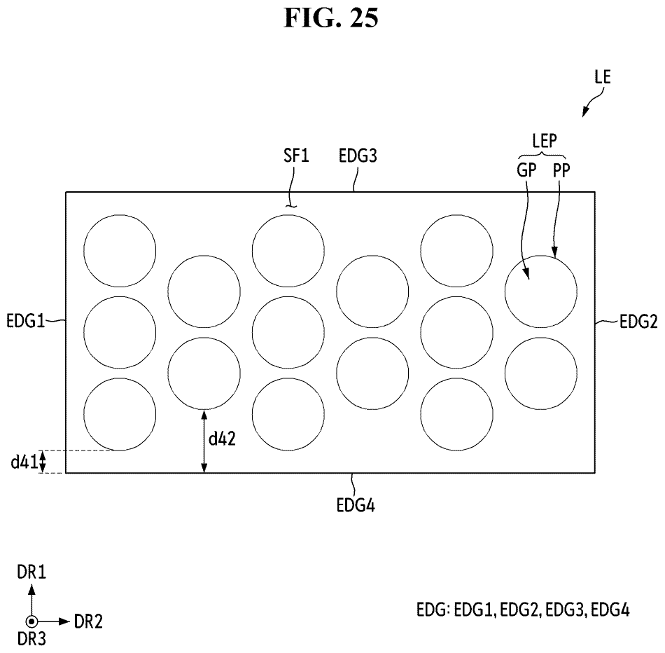

FIG. 23 is a plan view of a light emitting element LE according to one or more embodiments. FIG. 24 is a plan view of a light emitting element LE according to one or more embodiments. FIG. 25 is a plan view of a light emitting element LE according to one or more embodiments. For example, FIGS. 23 through 25 show embodiments different from the embodiments of FIGS. 21 and 22 in relation to light extraction patterns LEP that can be disposed on a light output surface SF1 of a light emitting element LE.

Referring to FIGS. 23 through 25, light extraction patterns LEP disposed in different columns in at least one direction may be spaced (e.g., spaced apart) from at least one end EDG of the light output surface SF1 by different distances. In one or more embodiments, as illustrated in FIGS. 23 and 24, a distance d12 or d11′ between light extraction patterns LEP arranged in an odd column in the first direction DR1 and a first end EDG1 of the light output surface SF1 may be different from a distance d11 or d12′ between light extraction patterns LEP arranged in an even column in the first direction DR1 and the first end EDG1 of the light output surface SF1. In one or more embodiments, as illustrated in FIG. 25, a distance d41 between light extraction patterns LEP arranged in an odd column in the second direction DR2 and a fourth end EDG4 of the light output surface SF1 may be different from a distance d42 between light extraction patterns LEP arranged in an even column in the second direction DR2 and the fourth end EDG4 of the light output surface SF1.

When the light extraction patterns LEP are spaced (e.g., spaced apart) from an end EDG of the light output surface SF1 by different distances in at least one of the first direction DR1 and the second direction DR2, the space utilization of the light output surface SF1 can be increased. Accordingly, when necessary, the light extraction patterns LEP can be arranged more densely to increase a light output rate of the light emitting element LE.

FIGS. 23 through 25 disclose embodiments in which the light extraction patterns LEP are spaced (e.g., spaced apart) from at least one end EDG of the light output surface SF1 of the light emitting element LE by different distances in units of two columns in at least one of the first direction DR1 and the second direction DR2. However, the present disclosure is not limited thereto. For example, the arrangement form or unit of the light extraction patterns LEP may vary according to embodiments.

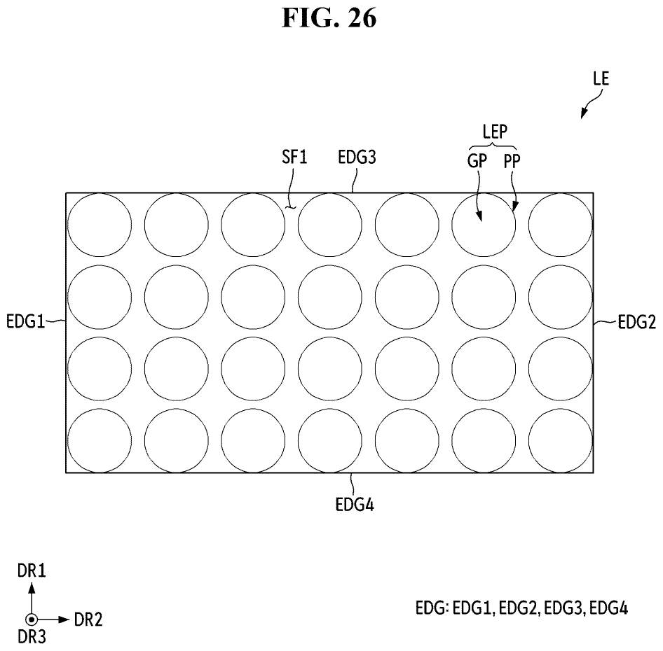

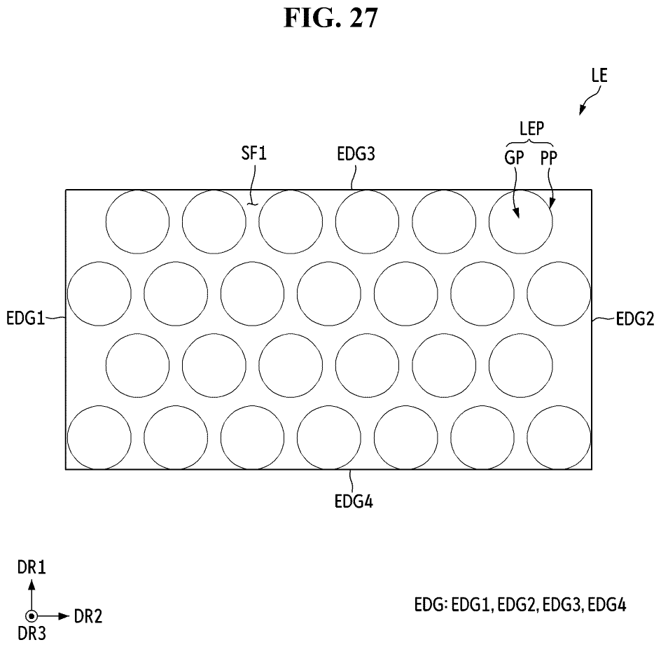

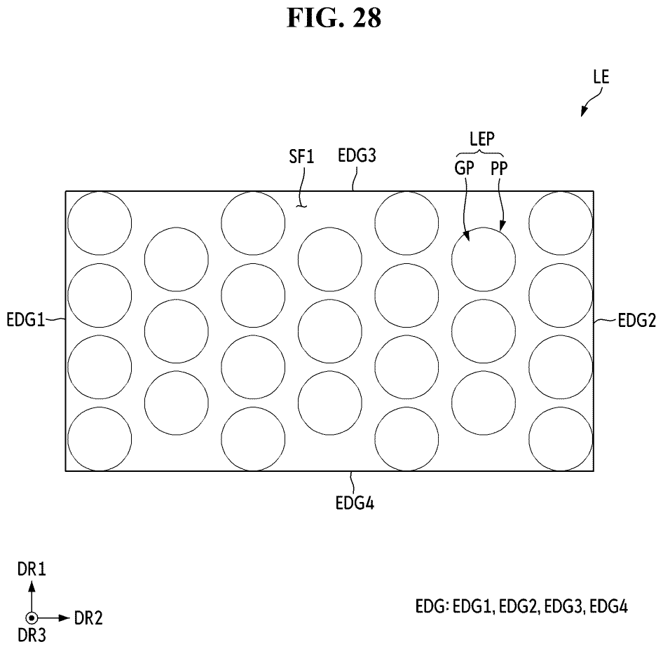

FIG. 26 is a plan view of a light emitting element LE according to one or more embodiments. FIG. 27 is a plan view of a light emitting element LE according to one or more embodiments. FIG. 28 is a plan view of a light emitting element LE according to one or more embodiments. For example, FIGS. 26 through 28 show embodiments different from the embodiments of FIGS. 21 through 25 in relation to light extraction patterns LEP that can be disposed on a light output surface SF1 of a light emitting element LE.

Referring to FIGS. 26 through 28, at least one of the light extraction patterns LEP may be in contact with an end EDG of the light output surface SF1. For example, from among the light extraction patterns LEP, light extraction patterns LEP located at outermost positions in at least one of the first direction DR1 and the second direction DR2 may be in contact with adjacent ends EDG of the light output surface SF1. Accordingly, an area where the light extraction patterns LEP are disposed may be expanded. Therefore, the light extraction patterns LEP can be disposed more efficiently on the light output surface SF1 of the light emitting element LE. For example, because the light extraction patterns LEP are disposed up to the ends of the light output surface SF1, a greater number of light extraction patterns LEP can be disposed on the light output surface SF1 of the light emitting element LE. Accordingly, the light output characteristics (e.g., the light output rate and/or the uniformity of light emission) of the light emitting element LE can be further improved.

In one or more embodiments, each of the light extraction patterns LEP in contact with the ends EDG of the light output surface SF1 may contact an end EDG of the light output surface SF1 at a protrusion portion PP. Accordingly, even if the light extraction patterns LEP contact the ends EDG of the light output surface SF1, groove portions GP of the light extraction patterns LEP may be located inside the ends EDG of the light output surface SF1. In addition, the protrusion portions PP of the light extraction patterns LEP may be covered with a protective layer INS. Accordingly, damage, defects, and/or changes in characteristics of the light emitting element LE can be prevented.

In one or more embodiments, the size, number, and/or interval of the light extraction patterns LEP disposed on the light output surface SF1 of the light emitting element LE may vary according to the size of the light emitting element LE and/or the size of the light extraction patterns LEP. For example, when the light emitting element LE includes the light output surface SF1 of a specific size, the number and/or density of the light extraction patterns LEP that can be disposed on the light output surface SF1 may increase as the size of each of the light extraction patterns LEP decreases. On the other hand, when each of the light extraction patterns LEP has a specific size, the number and/or density of the light extraction patterns LEP that can be disposed on the light output surface SF1 of the light emitting element LE may decrease as the size of the light emitting element LE decreases.

In one or more embodiments, the light extraction patterns LEP can be efficiently disposed on the light output surface SF1 by adjusting the size, shape, number, and/or arrangement density of the light extraction patterns LEP in consideration of at least one of the size and shape of the light output surface SF1. Accordingly, the light output characteristics of the light emitting element LE can be appropriately controlled or optimized. For example, the light extraction patterns LEP may be densely disposed on the light output surface SF1 to reduce or minimize the area of a portion where the light extraction patterns LEP are not disposed relative to the entire area of the light output surface SF1. Accordingly, the light output rate of the light emitting element LE can be improved.

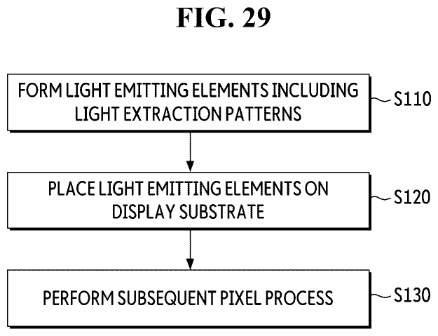

FIG. 29 is a flowchart illustrating a method of manufacturing a display device according to one or more embodiments. For example, FIG. 29 schematically illustrates a process of manufacturing a display device 10 that includes light emitting elements LE including light extraction patterns LEP as in the embodiments described above.

Referring to FIG. 29, the method of manufacturing the display device 10 according to the embodiment may include forming light emitting elements LE including light extraction patterns LEP (operation S110), placing the light emitting elements LE on a display substrate (operation S120), and performing a subsequent pixel process (operation S130).

In one or more embodiments, the forming of the light emitting elements LE including the light extraction patterns LEP (operation S110) may include forming the light emitting elements LE on a semiconductor substrate including patterns corresponding to the light extraction patterns LEP. In one or more embodiments, the forming of the light emitting elements LE including the light extraction patterns LEP (operation S110) may include forming the light extraction patterns LEP on a light output surface SF1 of each of the light emitting elements LE after transferring the light emitting elements LE formed on a semiconductor substrate onto a transfer substrate. The method of forming the light emitting elements LE including the light extraction patterns LEP will be described in detail later.

The placing of the light emitting elements LE on the display substrate (operation S120) may include preparing a display substrate including pixel electrodes PXE1 through PXE3 and placing the light emitting elements LE on the pixel electrodes PXE1 through PXE3. In one or more embodiments, the preparing of the display substrate may include forming a thin-film transistor layer TFTL including a substrate SUB and thin-film transistors TFT1 as illustrated in FIG. 7, 14, 17 or 19 and forming at least one of the pixel electrodes PXE1 through PXE3 and common electrodes (e.g., CE1 through CE3 of FIG. 17 or 19) on the thin-film transistor layer TFTL. When the light emitting elements LE are placed on a first organic layer 210 as in the embodiment of FIG. 7 or 17, the first organic layer 210 may be formed on a pixel electrode layer including at least one of the pixel electrodes PXE1 through PXE3 and the common electrodes CE1 through CE3.

The performing of the subsequent pixel process (e.g., the subsequent pixel formation process) (operation S130) may include forming elements on and/or around the light emitting elements LE after the placing of the light emitting elements LE in a display panel 100. For example, the performing of the subsequent pixel process (operation S130) may include forming a second organic layer 211 and a third organic layer 212 illustrated in FIG. 7, 14, 17 or 19 around the light emitting elements LE and forming a first capping layer CAP1 on the light emitting elements LE and the third organic layer 212. In addition, when a display panel 100 including a common electrode CE disposed on the light emitting elements LE as illustrated in FIG. 7 or 14 is manufactured, the common electrode CE and the first capping layer CAP1 may be sequentially formed on the third organic layer 212.

Additionally, when a display panel 100 in which a light control layer for changing or controlling the characteristics (e.g., the color or wavelength) of light emitted from subpixels SPX1 through SPX3 is disposed on a light emitting element layer including light emitting elements LE as illustrated in FIG. 7, 14, 17 or 19 is manufactured, the performing of the subsequent pixel process (operation S130) may further include forming the light control layer on the first capping layer CAP1. For example, a light blocking layer BM, light conversion layers QDL1 and QDL2, a light transmission layer TPL, etc. may be formed on the first capping layer CAP1, and a color filter layer including color filters CF1 through CF3 may be formed.

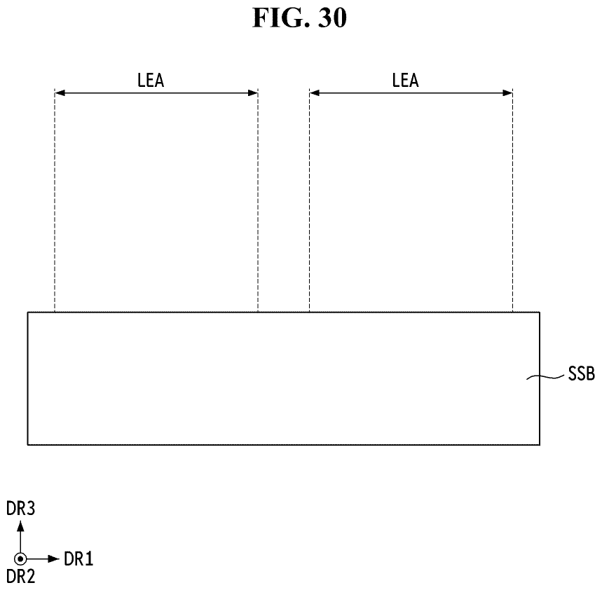

FIGS. 30 through 34 are cross-sectional views illustrating a method of manufacturing light emitting elements according to one or more embodiments. For example, FIGS. 30 through 34 sequentially illustrate a method of manufacturing light emitting elements LE including light extraction patterns LEP according to one or more embodiments. Manufacturing operations of FIGS. 30 through 34 may be included in operation S110 of FIG. 29.

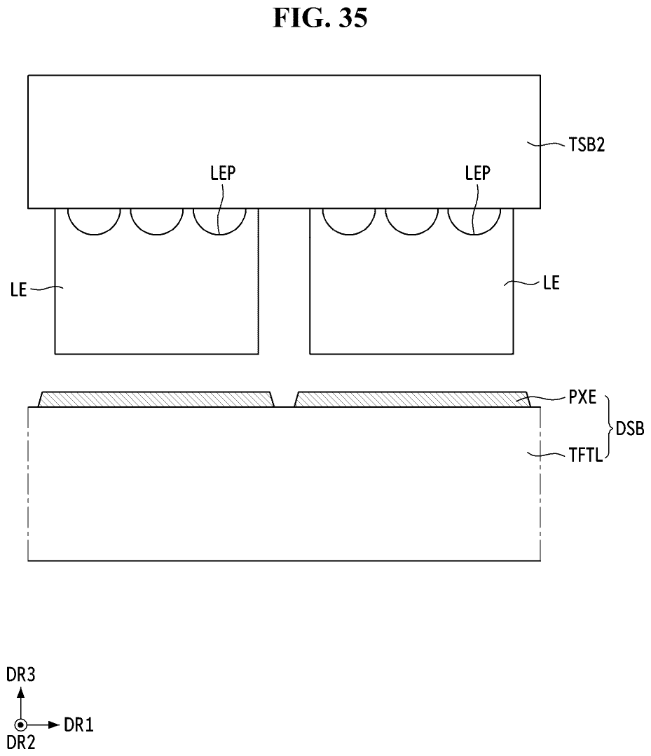

FIG. 35 is a cross-sectional view illustrating a method of placing light emitting elements according to one or more embodiments. For example, FIG. 35 schematically illustrates a method of placing light emitting elements LE including light extraction patterns LEP on pixel electrodes PXE of a display substrate DSB.

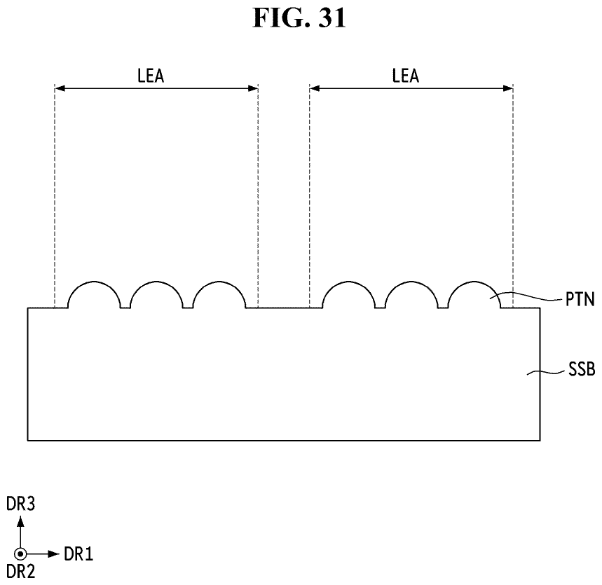

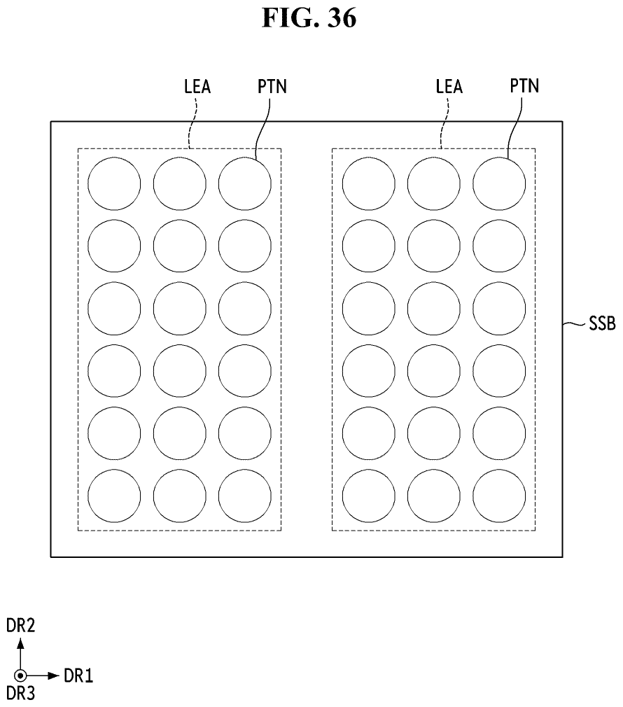

FIG. 36 is a plan view of a patterned semiconductor substrate according to one or more embodiments. For example, FIG. 36 is a plan view of a semiconductor substrate SSB including patterns PTN of FIG. 31.

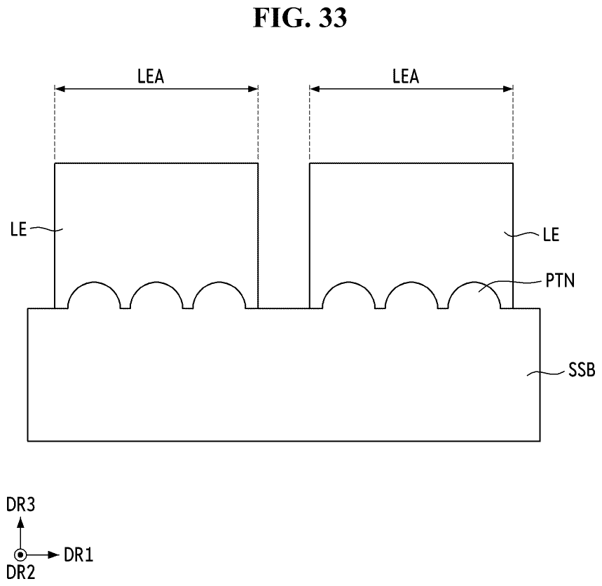

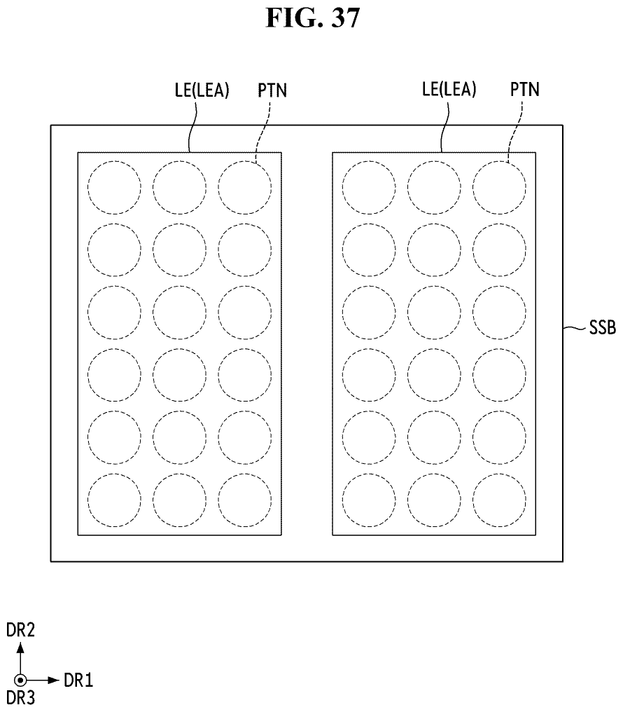

FIG. 37 is a plan view of a semiconductor substrate on which light emitting elements are formed according to one or more embodiments. For example, FIG. 37 is a plan view of a semiconductor substrate SSB on which light emitting elements LE of FIG. 33 are formed.

Referring to FIG. 30, first, a semiconductor substrate SSB is prepared. The semiconductor substrate SSB may be a manufacturing substrate for manufacturing light emitting elements LE. For example, the semiconductor substrate SSB may be a growth substrate suitable for epitaxial growth.

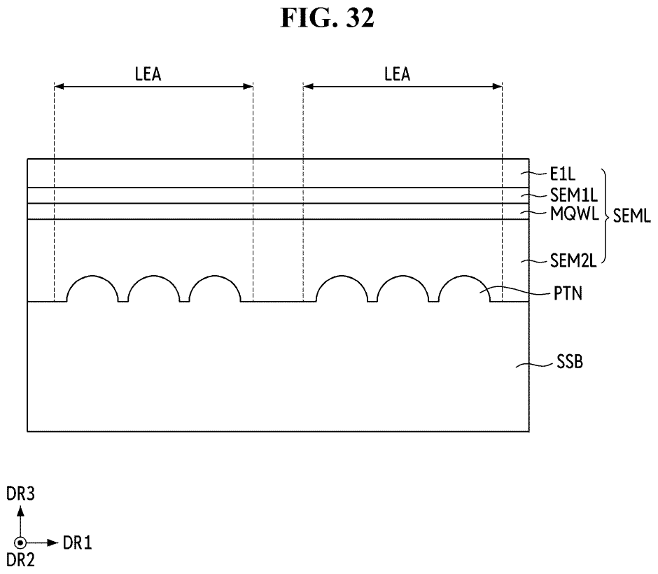

In one or more embodiments, the semiconductor substrate SSB may include a material such as GaAs, silicon (Si), sapphire, SiC, GaN, and/or ZnO. For example, the semiconductor substrate SSB may be a silicon wafer and/or a sapphire substrate. If the epitaxial growth of a semiconductor material layer (e.g., a semiconductor material layer SEML of FIG. 32) for manufacturing the light emitting elements LE can be smoothly performed, the type or material of the semiconductor substrate SSB is not particularly limited. A case where the semiconductor substrate SSB is a sapphire substrate will be described below as an example.

In one or more embodiments, a plurality of light emitting elements LE may be concurrently (e.g., simultaneously) formed on one semiconductor substrate SSB. For example, the semiconductor substrate SSB may include a plurality of light emitting element areas LEA for forming a plurality of light emitting elements LE. For ease of description, FIGS. 30 through 37 illustrate a portion of the semiconductor substrate SSB including two light emitting element areas LEA.

Referring to FIG. 31, the semiconductor substrate SSB may be patterned to form patterns PTN on an upper surface of the semiconductor substrate SSB. As illustrated in FIG. 36, the patterns PTN may be formed in the light emitting element areas LEA. For example, the patterns PTN may be formed only inside the light emitting element areas LEA and may not be formed in other areas.

The patterns PTN may be formed to form light extraction patterns LEP of the light emitting elements LE. The patterns PTN may be formed in each light emitting element area LEA to match the size, shape, and/or arrangement structure of the light extraction patterns LEP to be formed on a light output surface SF1 of each of the light emitting elements LE. For example, the patterns PTN may be formed in each light emitting element area LEA to match a given size, shape, and/or arrangement structure. In one or more embodiments, the patterns PTN may be formed by a patterning process including a photolithography process. For example, the patterns PTN may be formed by placing a mask pattern on the semiconductor substrate SSB through a photolithography process and then etching the semiconductor substrate SSB. However, the method of forming the patterns PTN is not limited thereto, and the patterns PTN may also be formed in other ways.

The patterns PTN may be aligned with the light emitting element areas LEA. For example, a mask pattern for forming the patterns PTN may be aligned with each light emitting element area LEA using an alignment key. Accordingly, uniform patterns PTN may be formed inside the light emitting element areas LEA. For example, the patterns PTN of the same shape, size, number, and/or arrangement form may be formed in the light emitting element areas LEA. Accordingly, the light emitting elements LE respectively formed in the light emitting element areas LEA in a subsequent process may include light extraction patterns LEP having substantially the same shape. In one or more embodiments, the patterned semiconductor substrate SSB may be a sapphire substrate patterned to include the patterns PTN according to one or more embodiments.

Referring to FIG. 32, a semiconductor material layer SEML may be formed on the semiconductor substrate SSB including the patterns PTN. The semiconductor material layer SEML may be formed to form a semiconductor stack STC of each of the light emitting elements LE and may be composed of multiple layers for forming each layer of the semiconductor stack STC. For example, the semiconductor material layer SEML may include a first semiconductor material layer SEM2L for forming a second semiconductor layer SEM2 of the semiconductor stack STC, a second semiconductor material layer MQWL for forming an active layer MQW of the semiconductor stack STC, and a third semiconductor material layer SEM1L for forming a first semiconductor layer SEM1 of the semiconductor stack STC. The first semiconductor material layer SEM2L, the second semiconductor material layer MQWL, and the third semiconductor material layer SEM1L may be sequentially formed on the semiconductor substrate SSB. The first semiconductor material layer SEM2L, the second semiconductor material layer MQWL, and the third semiconductor material layer SEM1L may include semiconductor materials for forming the second semiconductor layer SEM2, the active layer MQW, and the first semiconductor layer SEM1 of the semiconductor stack STC, respectively.

In one or more embodiments, the semiconductor material layer SEML may have a shape corresponding to the patterns PTN of the semiconductor substrate SSB. For example, a lower surface of the first semiconductor material layer SEM2L may have curves corresponding to the patterns PTN of the semiconductor substrate SSB.

The semiconductor material layer SEML may be formed by an epitaxial growth method using each semiconductor material. Here, the method of forming the semiconductor material layer SEML may be, but is not limited to, electron beam deposition, physical vapor deposition (PVD), chemical vapor deposition (CVD), plasma laser deposition (PLD), dual-type thermal evaporation, sputtering, and/or metal organic chemical vapor deposition (MOCVD).

In one or more embodiments, when light emitting elements LE including conductive layers E1 are to be manufactured, a conductive material layer E1L may be further formed on the semiconductor material layer SEML. The conductive material layer E1L may include a conductive material for forming the conductive layers E1. In one or more embodiments, the conductive material layer E1L may be formed by depositing a conductive material on the semiconductor material layer SEML.

Referring to FIG. 33, the semiconductor material layer SEML and the conductive material layer E1L may be etched to form the light emitting elements LE in the light emitting element area LEA, respectively. For example, as illustrated in FIG. 37, the light emitting elements LE may be formed only in the light emitting element areas LEA including the patterns PTN and may not be formed in other areas.

In one or more embodiments, the light emitting elements LE may be formed by etching the semiconductor material layer SEML and the conductive material layer E1L through a patterning process including a photolithography process, but the method of forming the light emitting elements LE is not limited thereto. The light emitting elements LE may include light extraction patterns LEP having a shape corresponding to the shape of the patterns PTN of the semiconductor substrate SSB. The light emitting elements LE may include light extraction patterns LEP having substantially the same size, shape, and/or arrangement structure.

The light emitting elements LE may have various shapes and/or structures according to one or more embodiments. When each of the light emitting elements LE further includes a protective layer INS and at least one electrode (e.g., at least one contact electrode CTE or a bonding electrode BDE) according to the embodiments described above, an additional process for forming the protective layer INS and the electrode may be performed after the etching of the semiconductor material layer SEML and the conductive material layer E1L.

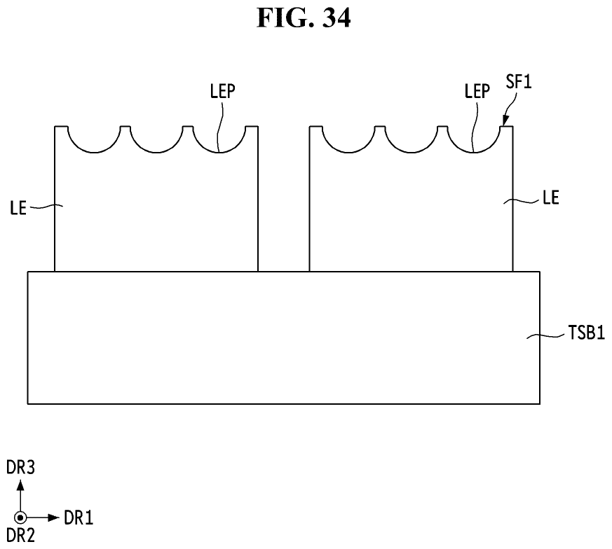

Referring to FIG. 34, the light emitting elements LE may be transferred onto a first transfer substrate TSB1 and may be separated from the semiconductor substrate SSB. In one or more embodiments, the first transfer substrate TSB1 may include an adhesive layer formed on an upper surface, and the light emitting elements LE may be transferred onto the adhesive layer on the first transfer substrate TSB1 to stably place the light emitting elements LE on the first transfer substrate TSB1.

In one or more embodiments, the light emitting elements LE may be separated from the semiconductor substrate SSB by a laser lift-off (LLO) process in which a laser is irradiated to the semiconductor substrate SSB. However, the method of separating the light emitting elements LE from the semiconductor substrate SSB is not limited thereto.

Referring to FIG. 35, after the light emitting elements LE are transferred from the first transfer substrate TSB1 to a second transfer substrate TSB2, they may be placed on a display substrate DSB. In one or more embodiments, the second transfer substrate TSB2 may include a laser separation layer formed on an upper surface. After the light emitting elements LE are transferred onto the laser separation layer on the second transfer substrate TSB2, the second transfer substrate TSB2 may be placed on the display substrate DSB such that the light emitting elements LE face the display substrate DSB. Each of the light emitting elements LE may be placed such that a lower surface opposite an upper surface on which the light extraction patterns LEP are disposed faces the display substrate DSB.

The second transfer substrate TSB2 may be made of a transparent material to allow light to pass therethrough. For example, the second transfer substrate TSB2 may include a transparent polymer such as polyimide, polyester, polyacrylic, poly epoxy, polyethylene, polystyrene, and/or polyethylene terephthalate. The laser separation layer may be a layer that can be separated by laser irradiation and may include, for example, a transparent polymer such as polyimide.

In a state where the light emitting elements LE are placed on the first transfer substrate TSB1, a surface of each of the light emitting elements LE may be brought into contact with the laser separation layer of the second transfer substrate TSB2, and then heat may be applied. Accordingly, each of the light emitting elements LE may be attached or fixed to the laser separation layer, and as the adhesive strength of the adhesive layer is weakened, each of the light emitting elements LE may be separated from the adhesive layer of the first transfer substrate TSB1.

The display substrate DSB may include pixel electrodes PXE. For example, the display substrate DSB may include pixel electrodes PXE disposed on a thin-film transistor layer TFTL. In one or more embodiments, each of the pixel electrodes PXE may be one of the first pixel electrode PXE1, the second pixel electrode PXE2, and the third pixel electrode PXE3 described above. The display substrate DSB may have various shapes according to one or more embodiments. Accordingly, only a rough shape of the display substrate DSB is illustrated in FIG. 35.

Next, the light emitting elements LE may be directly placed or connected onto the pixel electrodes PXE by a eutectic bonding method or may be placed or connected onto the pixel electrodes PXE by utilizing at least one connection electrode (e.g., the connection electrodes BE of FIG. 8 or the first connection electrode BE1 and the second connection electrode BE2 of FIG. 18). The method of placing or connecting the light emitting elements LE onto the pixel electrodes PXE1 through PXE3 or the resultant connection structure between the light emitting elements LE and the pixel electrodes PXE1 through PXE3 may vary according to one or more embodiments.

After the light emitting elements LE are placed on the pixel electrodes PXE, a subsequent pixel process may be performed to manufacture a display device 10. For example, a display panel 100 of the display device 10 may be manufactured by performing a subsequent pixel process including a process of forming a second organic layer 211 and a third organic layer 212, which surround the light emitting elements LE and a first capping layer CAP1 that covers the light emitting elements LE.

According to the above-described embodiment, light extraction patterns LEP may be uniformly formed on the light output surfaces SF1 of the light emitting elements LE. For example, the light emitting elements LE manufactured according to the embodiment may include light extraction patterns LEP of substantially the same size, shape, and/or number. Accordingly, the light output characteristics of the light emitting elements LE and subpixels SPX including the light emitting elements LE can be improved. For example, by placing the light emitting elements LE including uniform light extraction patterns LEP in the subpixels SPX, the light output rate of the light emitting elements LE and the subpixels SPX including the light emitting elements LE can be increased while the light output characteristics are made uniform. In addition, as the light output characteristics of the subpixels SPX become uniform, a viewing angle of the display device 10 may become uniform. For example, a difference in viewing angle between a plurality of display devices 10 including light emitting elements LE according to one or more embodiments can be prevented or reduced, and the operating characteristics of the display devices 10 can be improved or made uniform.

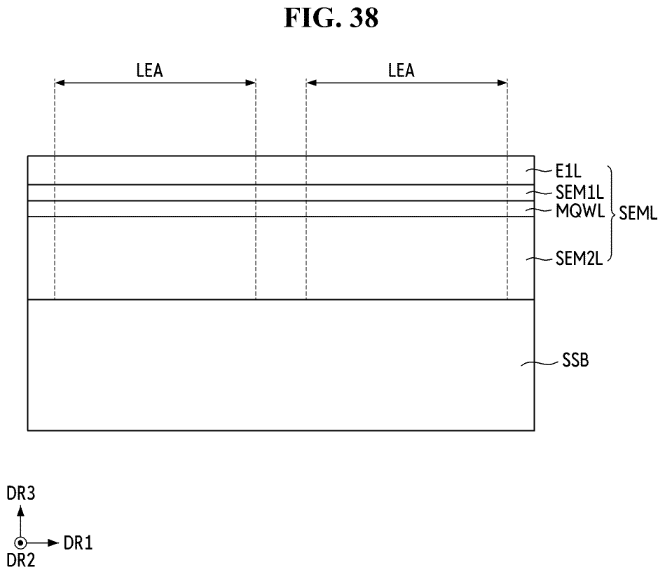

FIGS. 38 through 42 are cross-sectional views illustrating a method of manufacturing light emitting elements according to one or more embodiments. For example, FIGS. 38 through 42 sequentially illustrate a method of manufacturing light emitting elements LE including light extraction patterns LEP according to one or more embodiments. Manufacturing operations or steps of FIGS. 38 through 42 may be included in operation S110 of FIG. 29.

FIGS. 38 through 42 show an embodiment different from the embodiment of FIGS. 30 through 35 in relation to an operation or method of forming light extraction patterns LEP. In the description of the embodiment of FIGS. 37 through 41, descriptions overlapping those of the embodiment of FIGS. 38 through 42 will be omitted, and differences between the embodiments will be mainly described.

Referring to FIGS. 30 and 38, a semiconductor substrate SSB including light emitting element areas LEA may be prepared, and a semiconductor material layer SEML may be formed on the semiconductor substrate SSB. In one or more embodiments, a conductive material layer E1L may be further formed on the semiconductor material layer SEML. A process of patterning the semiconductor substrate SSB to form the patterns PTN of FIG. 31 may be omitted. For example, an upper surface of the semiconductor substrate SSB may not include the patterns PTN of FIG. 31 and may be substantially flat.

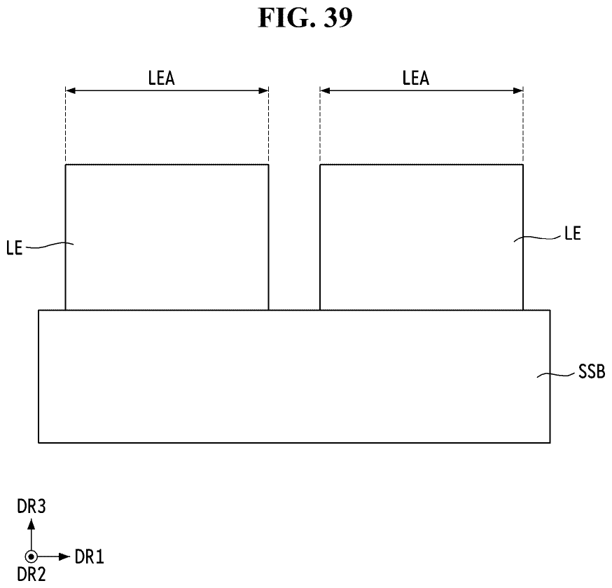

Referring to FIG. 39, light emitting elements LE may be formed by etching the semiconductor material layer SEML and the conductive material layer E1L. The light emitting elements LE may be disposed in the light emitting element areas LEA, respectively.

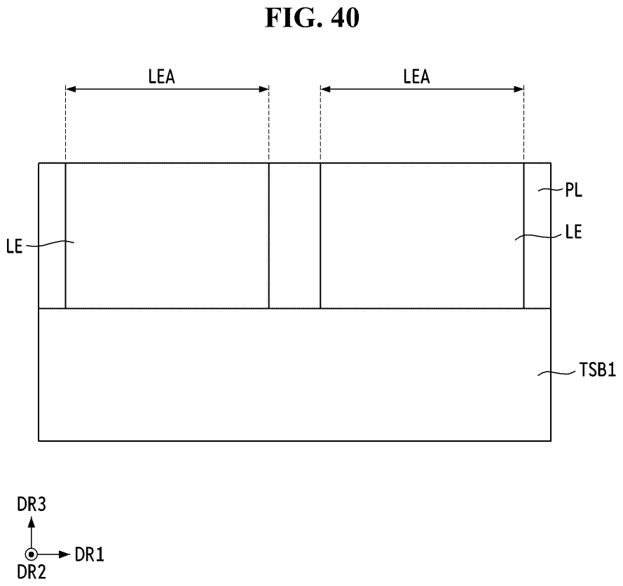

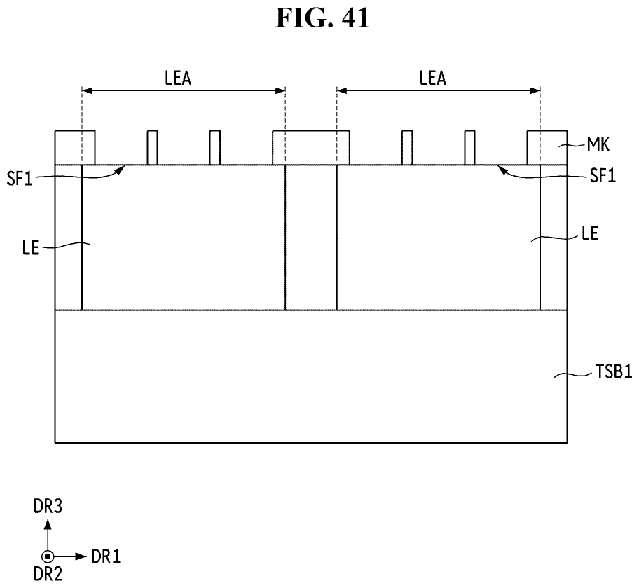

Referring to FIGS. 40 through 42, the light emitting elements LE may be separated from the semiconductor substrate SSB, and light extraction patterns LEP may be formed on a light output surface SF1 of each of the light emitting elements LE exposed as a result. For example, after a polymer is coated on the semiconductor substrate SSB and the light emitting elements LE of FIG. 39, the light emitting elements LE may be transferred onto a first transfer substrate TSB1 of FIG. 40, and the semiconductor substrate SSB may be separated from the light emitting elements LE. Accordingly, the light emitting elements LE and a polymer layer PL may be placed on the first transfer substrate TSB1. The polymer layer PL may include polyimide (PI) or glue, but the material of the polymer layer PL is not limited thereto. The first transfer substrate TSB1 may include an adhesive layer formed on an upper surface. Accordingly, the light emitting elements LE can be stably placed on the first transfer substrate TSB1. Next, as illustrated in FIG. 41, a mask MK may be placed on the light emitting elements LE and the polymer layer PL.

The mask MK may be formed to form the light extraction patterns LEP of the light emitting elements LE and may be formed in a shape that matches the size, shape, and/or arrangement structure of the light extraction patterns LEP to be formed on the light output surface SF1 of each of the light emitting elements LE. For example, the mask MK may include openings exposing areas where light extraction patterns LEP having a fine size (e.g., a diameter of several nanometers to hundreds of nanometers) are to be formed on the light output surface SF1 of each of the light emitting elements LE and may cover other areas. In one or more embodiments, the mask MK may include, but is not limited to, a photoresist material.

The mask MK may be aligned according to the alignment of the light emitting elements LE. In addition, the mask MK may have a uniform pattern corresponding to the light output surfaces SF1 of the light emitting elements LE. For example, the mask MK may be appropriately aligned on the light emitting elements LE so that light extraction patterns LEP of the same size, shape, and number are formed on the light output surfaces SF1 of the light emitting elements LE.

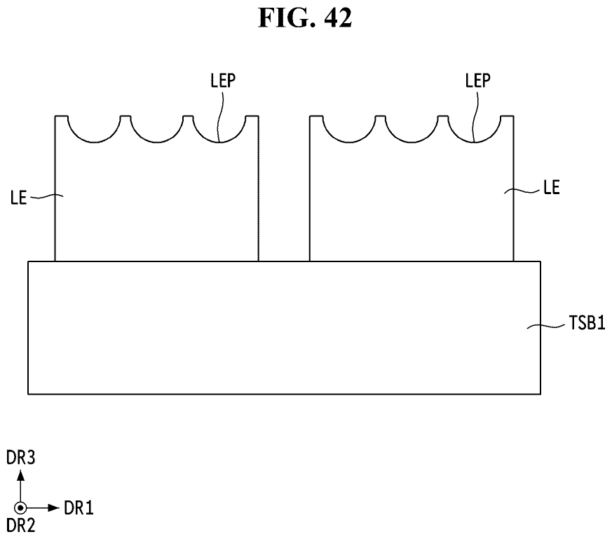

The light emitting elements LE may be etched by a patterning process using the mask MK to form the light extraction patterns LEP on the light output surface SF1 of each of the light emitting elements LE as illustrated in FIG. 42. For example, after the light extraction patterns LEP are formed by etching the light output surfaces SF1 of the light emitting elements LE using the mask MK, the mask MK and the polymer layer PL may be removed. In one or more embodiments, the light extraction patterns LEP may be formed by a photolithography process, a nano imprint process, and/or other types of patterning processes. The method of patterning the light emitting elements LE is not particularly limited as long as the light extraction patterns LEP of a desired shape and size can be formed.

Next, as described above with reference to FIGS. 34 and 35, the light emitting elements LE may be transferred to a second transfer substrate TSB2 and placed on a display substrate DSB. The light emitting elements LE may be placed on pixel electrodes PXE, respectively. The light emitting elements LE may be appropriately connected to the pixel electrodes PXE, respectively. Next, a subsequent pixel process may be performed to manufacture a display panel 100 of a display device 10.

As described above, according to one or more embodiments, uniform light extraction patterns LEP can be formed on light output surfaces SF1 of light emitting elements LE. For example, the light emitting elements LE may include light extraction patterns LEP of the same size, shape, and number. According to one or more embodiments, the light extraction patterns LEP can improve the light output efficiency of the light emitting elements LE while making the light output characteristics of the light emitting elements LE and subpixels SPX including the light emitting elements LE uniform. Accordingly, the light output characteristics of the subpixels SPX and a display device 10 including the subpixels SPX can be improved, and the viewing angle can be made uniform.

In addition, according to one or more embodiments, groove portions GP of the light extraction patterns LEP may be spaced (e.g., spaced apart) from a protective layer INS and thus disposed inside a light output surface SF1. For example, the light extraction patterns LEP may be disposed inside the light output surface SF1 of each of the light emitting elements LE so as not to contact the protective layer INS, or outermost light extraction patterns LEP may contact the protective layer INS at protrusion portions PP. Accordingly, side surfaces of a semiconductor stack STC can be more stably covered by the protective layer INS, and an appropriate distance can be secured between an electrode around the protective layer INS and a second semiconductor layer SEM2, thereby effectively preventing a short-circuit defect of each light emitting element LE and improving the efficiency of each light emitting element LE. In addition, even if a laser is irradiated to the light emitting elements LE during a process of separating the light emitting elements LE from a semiconductor substrate SSB or a transfer substrate (e.g., a first transfer substrate TSB1 or a second transfer substrate TSB2), damage to the light emitting elements LE at an interface between the semiconductor stack STC and the protective layer INS of each of the light emitting elements LE can be prevented or reduced. Accordingly, the luminance dispersion of the light emitting elements LE can be reduced or prevented, and the image quality and reliability of the display device 10 including the light emitting elements LE can be improved. Additionally, when the light emitting elements LE are bonded onto pixel electrodes PXE1 through PXE3 by irradiating a laser to the light emitting elements LE through a bonding method using a laser, because the light emitting elements LE include uniform light extraction patterns LEP, the incidence uniformity of the laser can be increased, and the light emitting elements LE can be stably bonded onto the pixel electrodes PXE1 through PXE3.

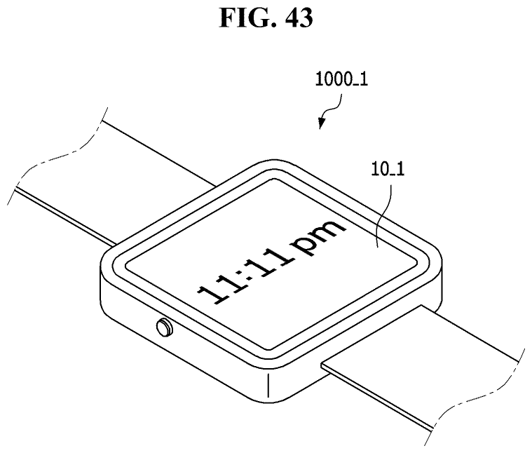

FIG. 43 is an example view of a smart watch 1000_1 including a display device 10_1 according to one or more embodiments. Referring to FIG. 43, the display device 10_1 according to the embodiment may be applied to the smart watch 1000_1 that is one of smart devices.

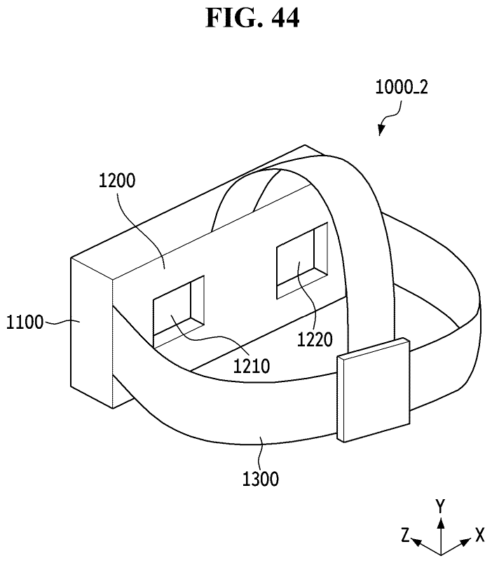

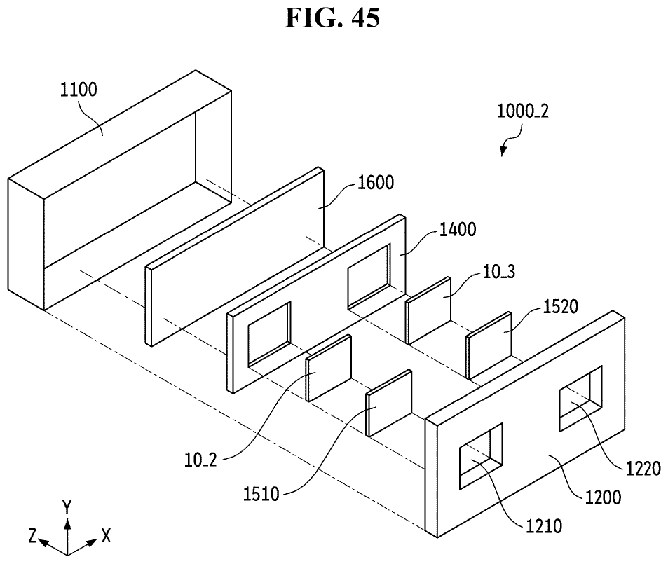

FIGS. 44 and 45 are example views of a virtual reality (VR) device including a display device according to one or more embodiments.

Referring to FIGS. 44 and 45, a head mounted display device 1000_2 according to one or more embodiments includes a first display device 102, a second display device 103, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 103 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 102 and the control circuit board 1600 and may be disposed between the second display device 10_3 and the control circuit board 1600. The middle frame 1400 supports and fixes the first display device 102, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 44 and 45, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

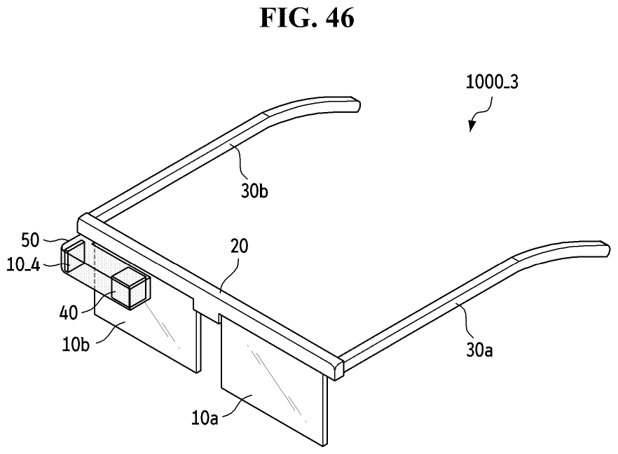

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1100 is implemented to be lightweight and small, the head mounted display device 1000_2 may include an eyeglass frame as illustrated in FIG. 46 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 46 is an example view of a VR device including a display device according to one or more embodiments. FIG. 46 illustrates a VR device 1000_3 to which a display device 10_4 according to one or more embodiments has been applied.

Referring to FIG. 46, the VR device 1000_3 according to one or more embodiments may be a device in the form of glasses. The VR device 1000_3 according to the embodiment may include the display device 104, a left lens 10a, a right lens 10b, a support frame 20, eyeglass frame legs 30a and 30b, a reflective member 40, and a display device housing 50.

In FIG. 46, a case where the VR device 1000_3 is a glasses-type display device including the eyeglass frame legs 30a and 30b is illustrated as an example. That is, the VR device 1000_3 according to the embodiment is not limited to the one illustrated in FIG. 46 and can be applied in various forms to various other electronic devices.

The display device housing 50 may include the display device 10_4 and the reflective member 40. An image displayed on the display device 104 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 46, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

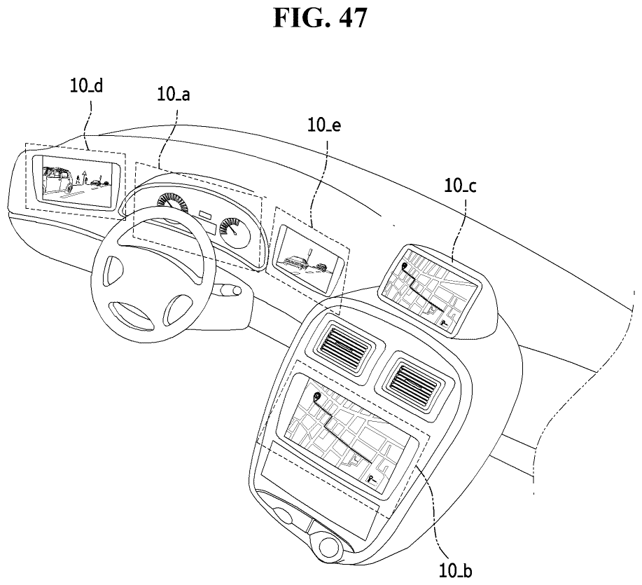

FIG. 47 is an example view illustrating a vehicle instrument cluster and center fascia including display devices according to one or more embodiments. FIG. 47 illustrates a vehicle to which display devices 10_a through 10_e according to one or more embodiments have been applied.

Referring to FIG. 47, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

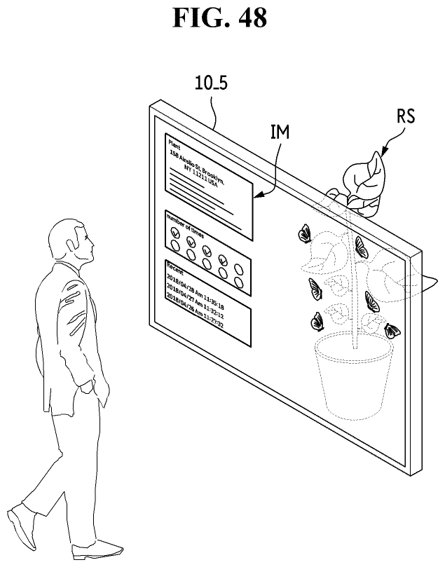

FIG. 48 is an example view of a transparent display device including a display device according to one or more embodiments.

Referring to FIG. 48, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a substrate;
pixel electrodes on the substrate; and
light emitting elements on the pixel electrodes,
wherein each of the light emitting elements comprises:
a semiconductor stack comprising a first semiconductor layer, an active layer on the first semiconductor layer, and a second semiconductor layer on the active layer;
light extraction patterns on a light output surface of the semiconductor stack and comprising groove portions that are spaced from an end of the light output surface and protrusion portions around the groove portions; and
a protective layer covering side surfaces of the semiconductor stack, and
wherein the light emitting elements comprise the light extraction patterns having a same shape.

2. The display device of claim 1, wherein the light extraction patterns are arranged in a same structure on the light output surface of each of the light emitting elements.

3. The display device of claim 1, wherein the light emitting elements comprise a same number of light extraction patterns.

4. The display device of claim 1, wherein an outermost light extraction pattern on the light output surface of each of the light emitting elements is spaced from the end of the light output surface and located inside the light output surface.

5. The display device of claim 4, wherein the light extraction patterns are arranged in a plurality of columns comprising a first column and a second column on the light output surface of each of the light emitting elements.

6. The display device of claim 5, wherein a light extraction pattern closest to a first end of the light output surface from among light extraction patterns in the first column and a light extraction pattern closest to the first end of the light output surface from among light extraction patterns in the second column are spaced from the first end of the light output surface by a same distance.

7. The display device of claim 5, wherein a light extraction pattern closest to a first end of the light output surface from among light extraction patterns in the first column and a light extraction pattern closest to the first end of the light output surface from among light extraction patterns in the second column are spaced from the first end of the light output surface by different distances.

8. The display device of claim 1, wherein at least one light extraction pattern from among the light extraction patterns contacts the end of the light output surface.

9. The display device of claim 8, wherein the at least one light extraction pattern contacts the end of the light output surface at the protrusion portion and is covered with the protective layer.

10. The display device of claim 1, wherein the light extraction patterns are formed on an upper surface of the second semiconductor layer.

11. A light emitting element comprising:
a semiconductor stack, which comprises a first semiconductor layer, an active layer on the first semiconductor layer, and a second semiconductor layer on the active layer;
a protective layer covering side surfaces of the semiconductor stack; and
light extraction patterns on a light output surface of the semiconductor stack, the light extraction patterns comprising groove portions that are spaced from an end of the light output surface and protrusion portions around the groove portions.

12. The light emitting element of claim 11, wherein an outermost light extraction pattern from among the light extraction patterns is spaced from the end of the light output surface and located inside the light output surface.

13. The light emitting element of claim 12, wherein the light extraction patterns are arranged in a plurality of columns comprising a first column and a second column along a first direction.

14. The light emitting element of claim 13, wherein a light extraction pattern closest to a first end of the light output surface from among light extraction patterns in the first column and a light extraction pattern closest to the first end of the light output surface from among light extraction patterns in the second column are spaced from the first end of the light output surface by a same distance.

15. The light emitting element of claim 13, wherein a light extraction pattern closest to a first end of the light output surface from among light extraction patterns in the first column and a light extraction pattern closest to the first end of the light output surface from among light extraction patterns in the second column are spaced from the first end of the light output surface by different distances.

16. The light emitting element of claim 11, wherein at least one of the light extraction patterns contacts the end of the light output surface.

17. An electronic device for providing an image, comprising:
a display device comprising:
a substrate;
pixel electrodes on the substrate; and
light emitting elements on the pixel electrodes,
wherein each of the light emitting elements comprises:
a semiconductor stack comprising a first semiconductor layer, an active layer on the first semiconductor layer, and a second semiconductor layer on the active layer;
light extraction patterns on a light output surface of the semiconductor stack and comprising groove portions that are spaced from an end of the light output surface and protrusion portions around the groove portions; and
a protective layer covering side surfaces of the semiconductor stack, and
wherein the light emitting elements comprise light extraction patterns having a same shape.
